(19) United States
(12) Patent Application Publication
(10) Pub. No.: US 2025/0147841 A1
(43) Pub. Date: May 8, 2025

(54) MEMORY DEVICE, OPERATION METHOD OF THE MEMORY DEVICE, AND PROGRAM

(71) Applicant: SEMICONDUCTOR ENERGY LABORATORY CO., LTD., Atsugi-shi, Kanagawa-ken (JP)

(72) Inventors: Kazuma FURUTANI, Atsugi, Kanagawa (JP); Yoshiyuki KUROKAWA, Sagamihara, Kanagawa (JP); Kazuaki OHSHIMA, Atsugi, Kanagawa (JP); Hideki UOCHI, Atsugi, Kanagawa (JP)

(21) Appl. No.: 18/835,451

(22) PCT Filed: Feb. 8, 2023
(86) PCT No.: PCT/IB2023/051093

§ 371 Date: Aug. 2, 2024

(30) Foreign Application Priority Data
Feb. 17, 2022 (JP) 2022-023069

(51) Int. Cl. G06F 11/10

(52) U.S. Cl. CPC G06F 11/102; G06F 11/1068

(57) ABSTRACT

A highly reliable memory device is provided. Of an information bit and a check bit forming a hamming code, the information bit having a larger bit length than the check bit is stored in a first memory portion, and the check bit is stored in the second memory portion. The hamming code is divided and stored in a plurality of memory portions, whereby occurrence of a soft error is suppressed. The first memory portion that needs a large memory capacity is formed using a Si transistor, and the second memory portion is formed using an OS transistor. A combination of memory scribing and bit interleaving achieves a highly reliable memory device.

### TECHNICAL FIELD

One embodiment of the present invention relates to a memory device, an operation method of the memory device, and a program.

Note that one embodiment of the present invention is not limited to the above technical field. Examples of the technical field of one embodiment of the present invention disclosed in this specification and the like include a semiconductor device, a display device, a light-emitting device, a power storage device, a memory device, an electronic device, a lighting device, an input device, an input/output device, a driving method thereof, and a manufacturing method thereof.

### BACKGROUND ART

In recent years, the amount of data subjected to processing has been increasing, which makes a demand for a memory device having a higher memory capacity. When miniaturization of a memory cell progresses with an increase in memory capacity and memory capacity per unit area increases, a soft error is likely to occur. A soft error refers to a defect of unintentional inversion of part of data stored in a memory cell. A soft error occurs when particle radiation such as alpha rays, beta rays, neutron beams, proton beams, heavy-ion beams, and meson beams enters a memory device. A soft error caused by one particle is also referred to as SEU (Single Event Upset).

A defect in which a 1-bit soft error occurs in one word (a piece of data) is referred to as SBU (Single Bit Upset). A defect in which soft errors of a plurality of bits occur in one word is referred to as MBU (Multi Bit Upset).

A soft error does not cause physical damage and thus is easily recovered. For example, an ECC (Error Check and Correct) memory that achieves SBU error detection and data correction is known. The ECC memory is used, for example, for an electronic device where occurrence of data error is forbidden, such as a computer used for scientific computation or used in a financial institution.

However, the ECC memory cannot perform MBU data correction. In Patent Document 1, an ECC memory is disclosed in which one word to be stored is divided into a plurality of pieces and a correction code (also referred to as “check data” or “check bit”) is added for each of the divided pieces to deal with MBU.

### REFERENCE

### Patent Document

[Patent Document 1] Japanese Translation of PCT International Application No. H5-508042

### SUMMARY OF THE INVENTION

### Problems to be Solved by the Invention

In an ECC memory, when data is stored (also represented by “written”), a check bit corresponding to data for one word to be stored (also referred to as “information bit”) is calculated, and the information bit and the check bit are stored in combination. Data obtained by combining the information bit and the check bit is referred to as a “hamming code”.

When the bit length of the hamming code is h, the bit length of the check bit is p, and the bit length of the information bit is j, the bit length h of the hamming code is denoted by h=p+j. In addition, there are h+1 combinations of the case where there is no error in the hamming code and the case where there is a 1-bit error in the hamming code. The information amount of the check bit is represented by 2^{p}. Thus, p and j need to satisfy the relation of Formula 1.

$$\begin{matrix}[ Formula 1 ] & \\ j ≦ {2}^{p} - p - 1 & ( Formula 1 )\end{matrix}$$

Furthermore, an “extension hamming code” which can detect whether there are errors of two or more bits or not by adding a 1-bit parity bit to the check bit is known. Therefore, the bit length of the extension hamming code is denoted by h+1. The extension hamming code cannot correct errors of two or more bits, but can detect whether there is MBU or not.

The proportion of the information bits in the hamming code or the extension hamming code is referred to as “transmission efficiency”. It is found from Formula 1 that the transmission efficiency of both the hamming code and the extension hamming code is improved as the bit length of the information bits increases. Thus, in the structure disclosed in Patent Document 1, transmission efficiency is significantly reduced, and a physical memory needs large memory capacity. That is, practical memory capacity is reduced.

An object of one embodiment of the present invention is to provide a highly reliable memory device. Another object of one embodiment of the present invention is to provide a memory device with low power consumption. Another object of one embodiment of the present invention is to provide a novel memory device. Another object of one embodiment of the present invention is to provide a novel operation method of a memory device.

Note that the objects of one embodiment of the present invention are not limited to the objects listed above. The objects listed above do not preclude the existence of other objects. The other objects are objects that are not described in this section and will be described below. The objects that are not described in this section will be derived from the description of the specification, the drawings, and the like and can be extracted as appropriate from the description by those skilled in the art. One embodiment of the present invention does not have to achieve all of the objects listed above and the other objects. One embodiment of the present invention achieves at least one of the objects listed above and the other objects.

### Means for Solving the Problems

(1) One embodiment of the present invention is a memory device including a check bit generation portion generating a check bit from an information bit, a first memory portion storing the information bit, a second memory portion storing the check bit, an error detection portion performing arithmetic processing using the information bit stored in the first memory portion and the check bit stored in the second memory portion, and an error correction portion correcting the information bit or the check bit in accordance with a result of the arithmetic processing; the first memory portion includes a first transistor; the second memory portion includes a second transistor; and a semiconductor layer of the second transistor and a semiconductor layer of the first transistor have different compositions.

(2) Another embodiment of the present invention is an operation method of a memory device including a check bit generation portion, an error detection portion, an error correction portion, a first memory portion including a first transistor, and a second memory portion including a second transistor. The operation method of the memory device includes the steps of generating a check bit in the check bit generation portion using an information bit; storing the information bit in the first memory portion; storing the check bit in the second memory portion; performing arithmetic processing in the error detection portion using the information bit stored in the first memory portion and the check bit stored in the second memory portion; correcting the information bit or the check bit in accordance with a result of the arithmetic processing in the error correction portion; storing the information bit subjected to the correction in the first memory portion; and storing the check bit subjected to the correction in the second memory portion.

(3) Another embodiment of the present invention is an operation method of a memory device including the steps of generating a check bit using an information bit; storing the information bit in a first memory portion; storing the check bit in a second memory portion; performing arithmetic processing using the information bit stored in the first memory portion and the check bit stored in the second memory portion; correcting the information bit or the check bit in accordance with a result of the arithmetic processing; in a case where the information bit is corrected, storing the information bit subjected to the correction in the first memory portion; and in a case where the check bit is corrected, storing the check bit subjected to the correction in the second memory portion.

In (2) or (3), it is preferable that configuration bits of the information bit be not stored in successive physical addresses. In addition, it is preferable that configuration bits of the check bit be not stored in successive physical addresses.

In each of (1) to (3), a Si transistor can be used as the first transistor, for example. Furthermore, an OS transistor can be used as the second transistor, for example.

(4) Another embodiment of the present invention is a program to make a memory device execute the above operation method.

### Effect of the Invention

According to one embodiment of the present invention, a highly reliable memory device can be provided. According to another embodiment of the present invention, a memory device with low power consumption can be provided. According to another embodiment of the present invention, a novel memory device can be provided. According to another embodiment of the present invention, a novel operation method of a memory device can be provided.

Note that the effects of one embodiment of the present invention are not limited to the effects listed above. The effects listed above do not preclude the presence of other effects. Accordingly, one embodiment of the present invention does not have the effects listed above in some cases. Note that the other effects are effects that are not described in this section and will be described below. The other effects are derived from the description of the specification, the drawings, and the like and can be extracted as appropriate from the description by those skilled in the art. One embodiment of the present invention has at least one of the effects listed above and the other effects.

### BRIEF DESCRIPTION OF THE DRAWINGS

FIG. 1A is a block diagram illustrating a structure example of a memory device 100. FIG. 1B is a diagram illustrating an extension hamming code.

FIG. 2 is a flow chart showing a writing operation.

FIG. 3 is a flow chart showing a reading operation.

FIG. 4 is a flow chart showing memory scribing.

FIG. 5A to FIG. 5C are diagrams illustrating structure examples of a memory portion.

FIG. 6A to FIG. 6C are each a diagram illustrating an example of a circuit structure applicable to a memory cell.

FIG. 7A and FIG. 7B are diagrams illustrating a structure example of a memory portion.

FIG. 8A and FIG. 8B are diagrams illustrating structure examples of a memory device.

FIG. 9A to FIG. 9D are diagrams illustrating bit interleave.

FIG. 10A to FIG. 10D are diagrams illustrating bit interleave.

FIG. 11A is a top view illustrating a structure example of a transistor. FIG. 11B and FIG. 11C are cross-sectional views illustrating the structure example of the transistor.

FIG. 12 is a diagram illustrating a structure example of a memory portion.

FIG. 13A is a diagram illustrating a structure example of a memory layer. FIG. 13B is a diagram illustrating an equivalent circuit in the memory layer.

FIG. 14 is a diagram illustrating a structure example of a memory portion.

FIG. 15A is a diagram illustrating a structure example of a memory layer. FIG. 15B is a diagram illustrating an equivalent circuit in the memory layer.

FIG. 16A and FIG. 16B are perspective views illustrating examples of electronic components.

FIG. 17A to FIG. 17J are diagrams illustrating examples of electronic devices.

FIG. 18A to FIG. 18E are diagrams illustrating examples of electronic devices.

FIG. 19A to FIG. 19C are diagrams illustrating examples of electronic devices.

FIG. 20 is a diagram illustrating an example of a device for space.

### MODE FOR CARRYING OUT THE INVENTION

Embodiments are described below with reference to the drawings. Note that the embodiments can be implemented in many different modes, and it is readily understood by those skilled in the art that modes and details can be changed in various ways without departing from the spirit and scope. Therefore, the present invention should not be construed as being limited to the description of embodiments below.

In this specification and the like, a semiconductor device refers to a device that utilizes semiconductor characteristics, and means a circuit including a semiconductor element (a transistor, a diode, a photodiode, and the like), a device including the circuit, and the like. The semiconductor device also means all devices that can function by utilizing semiconductor characteristics. For example, an integrated circuit, a chip including an integrated circuit, and an electronic component including a chip in a package are examples of the semiconductor device. Moreover, a memory device, a display device, a light-emitting device, a lighting device, an electronic device, and the like themselves might be semiconductor devices, or might include semiconductor devices.

In the drawings and the like in this specification, the size, the layer thickness, or the region is exaggerated for clarity in some cases. Therefore, embodiments of the present invention are not limited to the size, aspect ratio, and the like illustrated in the drawings. Note that the drawings schematically illustrate ideal examples, and shapes, values, and the like in embodiments of the present invention are not limited to those illustrated in the drawings.

Note that in the structures of the invention in the embodiments, the same reference numerals are used in common for the same portions or portions having similar functions in different drawings, and repeated description thereof is omitted in some cases. Furthermore, the same hatch pattern is used for the portions having similar functions, and the portions are not especially denoted by reference numerals in some cases. Moreover, some components are omitted in a perspective view, a top view, and the like for easy understanding of the drawings in some cases.

Ordinal numbers such as “first”, “second”, and “third” in this specification and the like are used to avoid confusion among components. Thus, the ordinal numbers do not limit the number of components. In addition, the ordinal numbers do not limit the order of components. In this specification and the like, for example, a “first” component in one embodiment can be referred to as a “second” component in other embodiments or the SCOPE OF CLAIMS. As another example, a “first” component in one embodiment in this specification and the like can be omitted in other embodiments or the SCOPE OF CLAIMS.

In this specification and the like, the terms for describing positioning, such as “over”, “under” “above”, and “below”, are sometimes used for convenience to describe the positional relation between components with reference to drawings. The positional relation between components is changed as appropriate in accordance with a direction in which each component is described. Thus, the positional relation is not limited to the terms described in the specification and the like, and can be described with another term as appropriate depending on the situation. For example, the expression “an insulator positioned over (on) a top surface of a conductor” can be replaced with the expression “an insulator positioned under (on) a bottom surface of a conductor” when the direction of a drawing illustrating these components is rotated by 180°.

Furthermore, the term “over” or “under” does not necessarily mean that a component is placed directly over or directly under and in direct contact with another component. For example, the expression “electrode B over insulating layer A” does not necessarily mean that the electrode B is formed over and in direct contact with the insulating layer A, and does not exclude the case where another component is provided between the insulating layer A and the electrode B.

The term “overlap”, for example, in this specification and the like does not limit a state such as the stacking order of components. For example, the expression “electrode B overlapping with insulating layer A” does not necessarily mean the state where the electrode B is formed over the insulating layer A, and does not exclude the state where the electrode B is formed under the insulating layer A and the state where the electrode B is formed on the right side (or the left side) of the insulating layer A.

Each of the terms “adjacent” and “proximity” in this specification and the like does not necessarily mean that a component is directly in contact with another component. For example, the expression “electrode B adjacent to insulating layer A” does not necessarily mean that the electrode B is formed in direct contact with the insulating layer A and does not exclude the case where another component is provided between the insulating layer A and the electrode B.

In this specification and the like, the terms “film”, “layer”, and the like can be interchanged with each other depending on the situation. For example, the term “conductive layer” can be replaced with the term “conductive film” in some cases. For another example, the term “insulating film” can be replaced with the term “insulating layer” in some cases. Alternatively, the term “film”, “layer”, or the like is not used and can be interchanged with another term depending on the case or the situation. For example, the term “conductive layer” or “conductive film” can be changed into the term “conductor” in some cases. Alternatively, the term “conductor” can be changed into the term “conductive layer” or “conductive film” in some cases. As another example, the term “insulating layer” or “insulating film” can be changed into the term “insulator” in some cases. Alternatively, the term “insulator” can be changed into the term “insulating layer” or “insulating film” in some cases.

Note that voltage refers to a difference between potentials of two points, and a potential refers to electrostatic energy (electric potential energy) of a unit charge at a given point in an electrostatic field. Note that in general, a potential difference between a potential at a given point and a reference potential (e.g., a ground potential) is simply called potential or voltage, and potential and voltage are used as synonymous words in many cases. Therefore, in this specification and the like, potential is interchangeable with voltage and voltage is interchangeable with potential unless explicitly stated.

In this specification and the like, the term “electrode”, “wiring”, “terminal”, or the like does not limit the function of a component. For example, an “electrode” is used as part of a “wiring” in some cases, and vice versa. Furthermore, for example, the term “electrode” or “wiring” also includes the case where a plurality of “electrodes” or “wirings” are formed in an integrated manner. For example, a “terminal” is used as part of a “wiring” or an “electrode” in some cases, and vice versa. Furthermore, the term “terminal” also includes the case where a plurality of “electrodes”, “wirings”, “terminals”, or the like are formed in an integrated manner, for example. Therefore, for example, an “electrode” can be part of a “wiring” or a “terminal”, and a “terminal” can be part of a “wiring” or an “electrode”. Moreover, the terms “electrode”, “wiring”, “terminal”, and the like are sometimes replaced with the term “region” or the like depending on the case.

In this specification and the like, the terms “wiring”, “signal line”, “power supply line”, and the like can be interchanged with each other depending on the case or the situation. For example, the term “wiring” can be changed into the term “signal line” in some cases. For another example, the term “wiring” can be changed into the term “power supply line” or the like in some cases. Conversely, the term “signal line”, “power supply line”, or the like can be changed into the term “wiring” in some cases. The term “power supply line” or the like can be changed into the term “signal line” or the like in some cases. Conversely, the term “signal line” or the like can be changed into the term “power supply line” or the like in some cases. The term “potential” that is applied to a wiring can be changed into the term “signal” or the like depending on the case or the situation. Conversely, the term “signal” or the like can be changed into the term “potential” in some cases.

In this specification, “parallel” indicates a state where two straight lines are placed at an angle greater than or equal to −10° and less than or equal to 10°. Thus, the case where the angle is greater than or equal to −5° and less than or equal to 5° is also included. In addition, “approximately parallel” or “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Thus, the case where the angle is greater than or equal to 85° and less than or equal to 95° is also included. Furthermore, “approximately perpendicular” or “substantially perpendicular” indicates a state where two straight lines are placed at an angle greater than or equal to 60° and less than or equal to 120°.

In this specification and the like, the terms “identical”, “the same”, “equal”, “uniform”, and the like (including synonyms thereof) used in describing calculation values and measurement values contain an error of +20% unless otherwise specified.

In the drawings and the like in this specification, arrows indicating the X direction, the Y direction, and the Z direction are illustrated in some cases. In this specification and the like, the “X direction” is a direction along the X-axis, and the forward direction and the reverse direction are not distinguished in some cases, unless otherwise specified. The same applies to the “Y direction” and the “Z direction”. The X direction, the Y direction, and the Z direction are directions intersecting with each other. More specifically, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

In this specification and the like, when a plurality of components are denoted by the same reference numerals, and in particular need to be distinguished from each other, an identification sign such as “A”, “b”, “_1”, “[n]”, or “[m, n]” is sometimes added to the reference numerals. For example, a conductor 542 is divided and shown as a conductor 542a and a conductor 542b in some cases.

### Embodiment 1

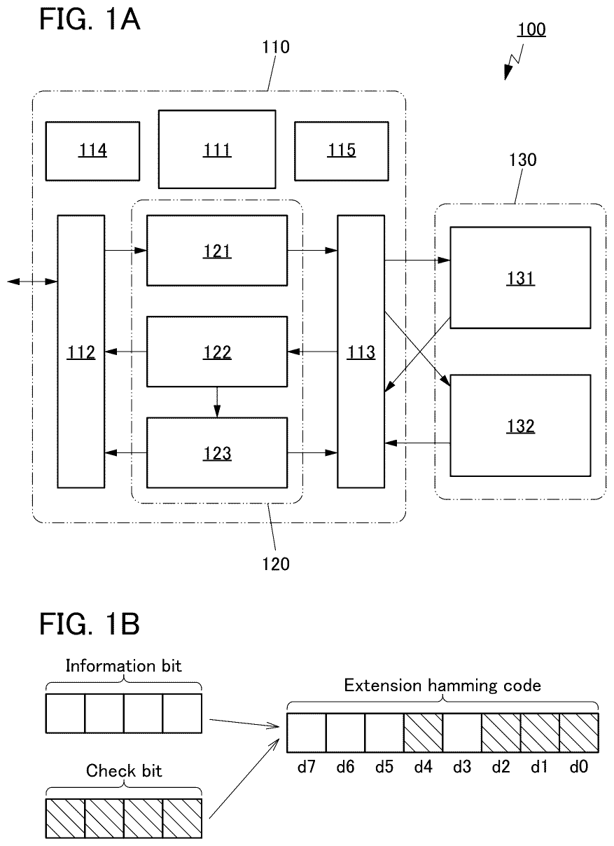

A memory device 100 of one embodiment of the present invention will be described. FIG. 1A is a block diagram illustrating a structure example of the memory device 100.

### <Structure Example>

The memory device 100 includes a control means 110 and a memory means 130. The control means 110 includes a control portion 111, an external interface 112, a memory interface 113, and an ECC portion 120. The control portion 111 has a function of controlling the operations of the external interface 112, the memory interface 113, an application memory 114, a working memory 115, and the ECC portion 120.

The external interface 112 has a function of controlling synchronization between an external device and the memory device 100. Input of an information bit supplied from the external device and output of an information bit stored in the memory device 100 to the external device are performed through the external interface 112.

The ECC portion 120 includes a check bit generation portion 121, an error detection portion 122, and an error correction portion 123. The check bit generation portion 121 has a function of generating a check bit corresponding to an information bit. As described above, data obtained by combining an information bit and the information bit is referred to as a “hamming code” or an “extension hamming code”.

As an example, the case where an extension hamming code corresponding to 4-bit information bits is generated is described. First, 4-bit check bits corresponding to the 4-bit information bits are generated. Next, the 4-bit information bits and the generated 4-bit check bits are combined to generate an 8-bit extension hamming code. When addresses of configuration bits of the extension hamming code is d0 to d7, the information bits are arranged in d3, d5, d6, and d7, and the check bits are arranged in do, d1, d2, and d4 (see FIG. 1B).

In the case where an extension hamming code corresponding to 8-bit information bits is generated, the bit length of a check bit needs to be 5 bits. Therefore, the bit length of the extension hamming code is 13 bits. When addresses of configuration bits of the extension hamming code are d0 to d12, the information bits are arranged in d3, d5, d6, d7, d9, d10, d11, and d12, and the check bits are arranged in do, d1, d2, d4, and d8.

Furthermore, unless otherwise specified, a “hamming code” includes an “extension hamming code” in this specification and the like.

The error detection portion 122 has a function of determining whether there is an error in a hamming code or not. The error correction portion 123 has a function of correcting an error in a hamming code.

The memory interface 113 has a function of controlling synchronization between the control means 110 and the memory means 130. Specifically, an information bit and a check bit are written to the memory means 130 through the memory interface 113. The information bit and the check bit stored in the memory means 130 are read into the control means 110 through the memory interface 113.

The application memory 114 has a function of storing a program and a parameter related to the operation of the memory device 100. The memory device 100 has a function of operating in accordance with the program stored in the application memory 114. For example, the memory device 100 executes a data writing operation, a data reading operation, memory scribing, bit interleave, and the like in accordance with the program.

As the application memory 114, a nonvolatile memory such as a ROM (Read Only Memory) or a flash memory can be used. A volatile memory such as a RAM (Random Access Memory) may be provided in part of the application memory 114.

The program or the parameter related to the operation of the memory device 100 is changed through the external interface 112. The program or the parameter supplied to the memory device 100 through the external interface 112 is stored in the application memory 114.

The working memory 115 functions as a temporary memory portion used when the control portion 111, the ECC portion 120, and the like execute arithmetic processing. A volatile memory such as a DRAM (Dynamic Random Access Memory) is used as the working memory 115. Note that a nonvolatile memory may be provided in part of the working memory 115.

When the memory device 100 is activated, a program and a parameter stored in the application memory 114 are read into the working memory 115 for the execution of the program. Note that as necessary, not the program and the parameter stored in the application memory 114 but a program or a parameter supplied through the external interface 112 may be read into the working memory 115. A memory space is assigned to part of the working memory 115 as a workspace at the time of executing a program.

The memory means 130 includes a first memory portion 131 and a second memory portion 132. An information bit is stored in the first memory portion 131, and a check bit is stored in the second memory portion 132. When the information bit and the check bit are stored separately in the different memory portions, the probability of occurrence of a soft error can be reduced, and the memory device 100 with high reliability can be achieved.

In addition, as described above, when one information bit is divided into a plurality of pieces and a check bit is generated for each of the divided pieces, transmission efficiency is decreased. When one information bit is not divided into a plurality of pieces and the information bit and a check bit are separately stored in different memory portions, high transmission efficiency and a reduction in probability of occurrence of a soft error can be achieved. Thus, a memory device with high practical memory capacity and high reliability can be obtained.

As a memory element used in the first memory portion 131 and the second memory portion 132, it is preferable to use a memory element using a transistor including an oxide semiconductor in a semiconductor layer where a channel is formed (also referred to as an “OS transistor”) (such a memory element is also referred to as an “OS memory”). A soft error is less likely to occur in the OS memory, and thus the reliability of the memory device 100 can be increased.

In the case where the bit length of an information bit is 4 bits, the bit length of a check bit included in an extension hamming code is 4 bits. In the case where the bit length of an information bit is 32 bits, the bit length of a check bit included in an extension hamming code is 7 bits. In the case where the bit length of an information bit is 64 bits, the bit length of a check bit included in an extension hamming code is 8 bits. When the bit length of an information bit is more than 4 bits in this manner, the bit length of an information bit is larger than the bit length of a check bit.

Therefore, the first memory portion 131 storing the information bit preferably has a larger memory capacity than the second memory portion 132 storing the check bit. In order to achieve a memory portion with large memory capacity, a memory element using a transistor including silicon in a semiconductor layer where a channel is formed (also referred to as a “Si transistor”) (such a memory element is also referred to as a “Si memory”) may be used as the memory element in the first memory portion 131. Si memories can be mounted at a higher density than OS memories, and a memory portion with large memory capacity can be easily achieved. For example, a DRAM, an SRAM, a flash memory, or the like can be used as the first memory portion 131. Therefore, Si memories may be used as the first memory portion 131 and the second memory portion 132 as needed.

It is preferable that a Si memory be used as the first memory portion 131 that needs large memory capacity and an OS memory be used as the second memory portion 132. When a Si memory and an OS memory are used in combination in the memory means 130, a memory device with high reliability and large memory capacity can be achieved.

Although this embodiment describes an operation example in which an information bit is written to the first memory portion 131 and a check bit is written to the second memory portion 132, one embodiment of the present invention is not limited thereto. For example, a hamming code may be generated by combining an information bit and a check bit, part of the hamming code (e.g., the first half of bits) may be written to the first memory portion 131, and the other (e.g., the latter half of bits) may be written to the second memory portion 132. Note that in this case, a step of generating the hamming code by combining the information bit and the check bit and a step of dividing the generated hamming code for each of a plurality of memory portions are necessary; thus, an increase in processing time and an increase in power consumption occur.

The memory means 130 may include three or more memory portions. When an information bit and a check bit are separately stored in a plurality of memory portions, the frequency of occurrence of MBU is reduced, and the memory device 100 can have high reliability.

Although in the block diagram illustrated in FIG. 1, components are classified by their functions and illustrated as independent blocks, it is difficult to completely divide actual components according to their functions and one component can relate to a plurality of functions. Thus, the memory device 100 of one embodiment of the present invention does not necessarily include all the components illustrated in FIG. 1. The memory device 100 of one embodiment of the present invention may include a component that is not illustrated in FIG. 1.

### <Operation Example>

Next, a writing operation and a reading operation (an operation method) of the memory device 100 are described. The control portion 111 has a function of executing a writing operation, a reading operation, a memory scribing operation, and the like in accordance with a program read into the working memory 115.

### <<Writing Operation>>

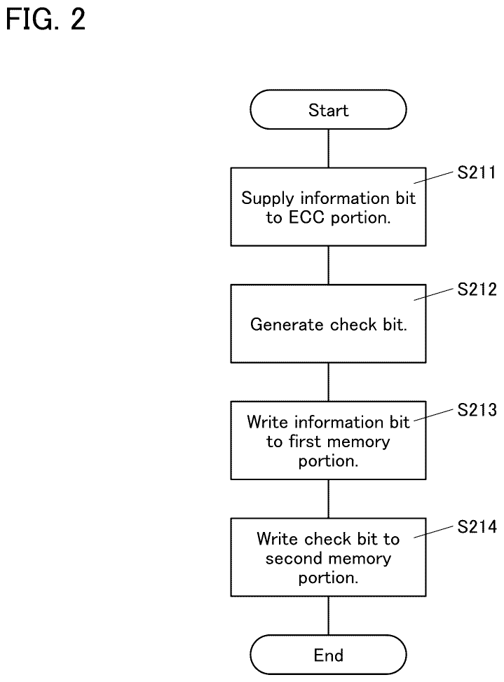

An operation of writing an information bit to the memory device 100 is described with reference to a flow chart in FIG. 2.

### [Step S211]

An information bit to be written to the memory device 100 is supplied from an external device to the ECC portion 120 through the external interface 112.

### [Step S212]

When the information bit is supplied to the ECC portion 120, the check bit generation portion 121 generates a check bit corresponding to the information bit.

### [Step S213]

The information bit is supplied to the memory means 130 through the external interface 112. The information bit is written to the first memory portion 131 included in the memory means 130.

### [Step S214]

The check bit is supplied to the memory means 130 through the external interface 112. The check bit is written to the second memory portion 132 included in the memory means 130.

Note that the execution order of Step S213 and Step S214 may be reversed. Alternatively, Step S213 and Step S214 may be executed at the same time. In the case where a plurality of information bits are written to the memory device 100, Step S211 to Step S214 are repeated for each information bit. The check bit generation portion 121 generates a check bit for each of the plurality of information bits.

### <<Reading Operation>>

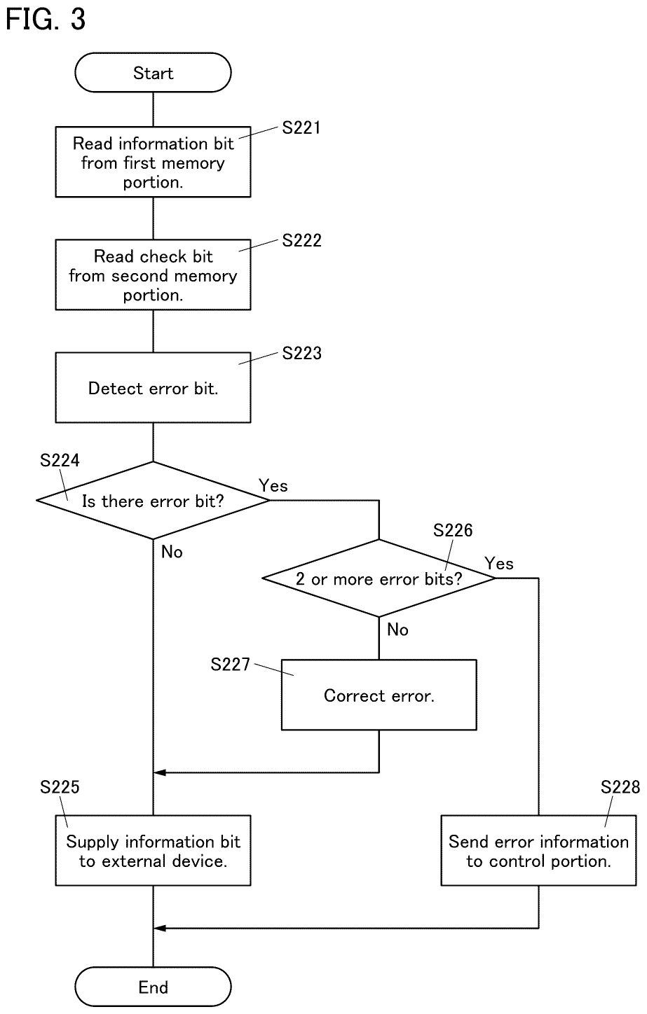

An operation of reading an information bit stored in the memory device 100 is described with reference to a flow chart in FIG. 3.

### [Step S221]

An information bit stored in the first memory portion 131 is supplied to the error detection portion 122 included in the ECC portion 120 through the memory interface 113.

### [Step S222]

A check bit stored in the second memory portion 132 is supplied to the error detection portion 122 included in the ECC portion 120 through the memory interface 113. Note that the check bit to be read out in Step S222 is a check bit corresponding to the information bit read out in Step S221.

Note that the execution order of Step S221 and Step S222 may be reversed. Alternatively, Step S221 and Step S222 may be executed at the same time. In Step S221 and Step S222, the information bit and the check bit corresponding to each other are read out.

### [Step S223]

The error detection portion 122 detects whether there is an error bit or not using the information bit read out in step S221 and the check bit read out in step S222. In other words, the error detection portion 122 detects an error in a hamming code including the information bit read out in step S221 and the check bit read out in step S222.

### [Step S224] and [Step S225]

In Step S224, whether there is an error bit or not is determined. When there is no error bit, the information bit is supplied to an external device through the external interface 112 (Step S225). When there is an error bit, Step S226 is performed.

### [Step S226]

In the case where the number of detected error bits is one, Step S227 is performed. In the case where the number of detected error bits is greater than or equal to two, Step S228 is performed.

### [Step S227]

The error correction portion 123 corrects an error. When the number of error bits is one, a position of the error bit can be specified and an error can be corrected using the hamming code including the information bit and the check bit. The error correction portion 123 performs arithmetic processing for specifying the position of the error bit using the information bit and the check bit.

The error correction portion 123 corrects the error bit included in the information bit or the check bit in accordance with the result of the arithmetic processing. In the case where the error bit is included in the information bit, the information bit is subjected to error correction. In the case where the error bit is included in the check bit, the check bit is subjected to error correction.

After that, Step S225 is performed, whereby an information bit with no error can be supplied to the external device.

### [Step S228]

In the case where the number of error bits is greater than or equal to two, error correction cannot be performed. In the case where the number of error bits is greater than or equal to two, the control portion 111 is notified that error correction cannot be performed. The control portion 111 does not supply the information bit to the external device and supplies the error information to the external device.

In the case where error correction is performed in Step S227, the information bit subjected to the error correction or the check bit subjected to the error correction may be written to the memory means 130. Specifically, in the case where the information bit is subjected to error correction, the information bit including an error stored in the first memory portion 131 is overwritten with the corrected information bit. In the case where the check bit is subjected to error correction, the check bit including an error stored in the second memory portion 132 is Overwritten with the Corrected Check Bit.

### <<Memory Scribing>>

Memory scribing refers to an operation in which error bit detection of data (an information bit and a check bit) stored in the memory means 130 is performed and error correction is performed every given period. When MBU (errors of two or more bits) occurs in one word of the hamming code, error correction cannot be performed; thus, memory scribing is preferably performed every given period.

The memory scribing is performed every given period, whereby the occurrence frequency of MBU can be reduced. Consequently, the memory device 100 can have higher reliability. The memory scribing is performed in the first memory portion 131 and the second memory portion 132. The timing of the memory scribing in the first memory portion 131 and the timing of the memory scribing in the second memory portion 132 may be the same or different from each other. The executing cycle of the memory scribing in the first memory portion 131 and the executing cycle of the memory scribing in the second memory portion 132 may be the same or different from each other.

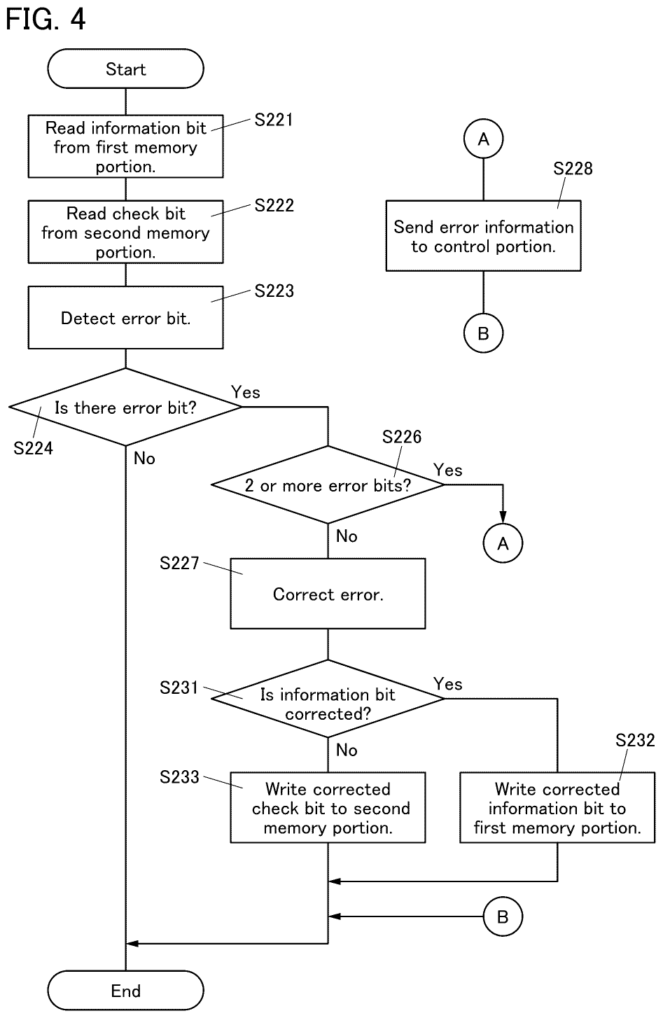

Memory scribing will be described with reference to a flow chart in FIG. 4.

The memory scribing can be regarded as a variation of the reading operation. Step S221 to Step S224 and Step S226 to Step S228 are performed in a manner similar to those of the reading operation. However, in the case where it is determined that there is no error bit in Step S224, the memory scribing is terminated.

After the error correction is performed in Step S227, which of the information bit and the check bit is subjected to the error correction is determined in Step S231. In the case where the information bit is subjected to the error correction, the corrected information bit is written to the first memory portion 131 (Step S232). At this time, the information bit including an error that is stored in the first memory portion 131 is overwritten with the corrected information bit.

In the case where the check bit is subjected to the error correction, the corrected check bit is written to the second memory portion 132 (Step S233). At this time, the check bit including an error that is stored in the second memory portion 132 is overwritten with the corrected check bit.

In the above manner, the memory scribing can be achieved.

This embodiment can be implemented in combination with the other embodiments described in this specification as appropriate.

### Embodiment 2

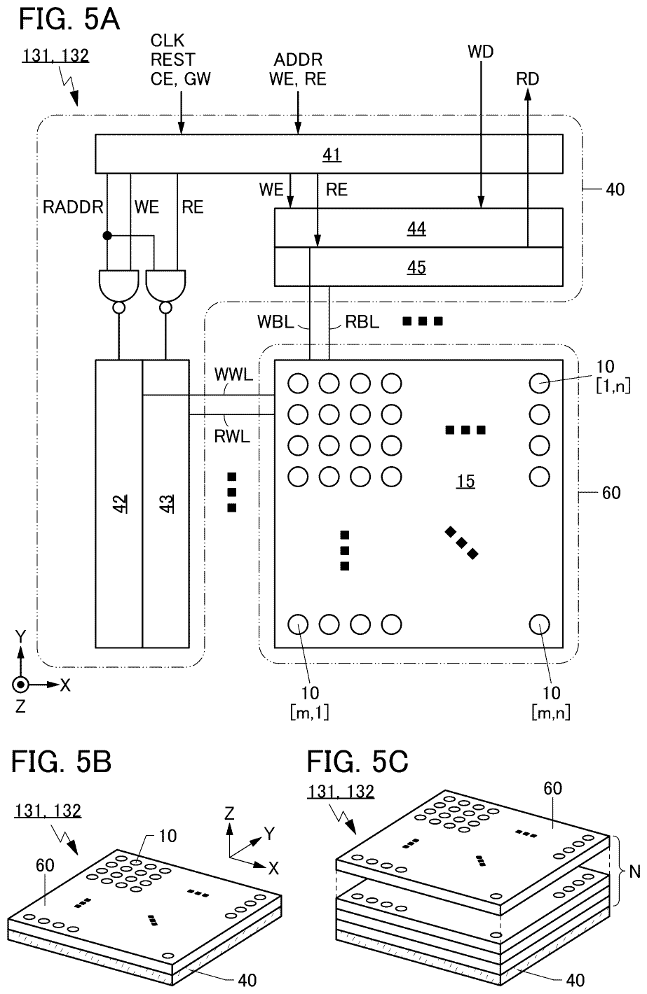

In this embodiment, structure examples of the first memory portion 131 and the second memory portion 132 are described. FIG. 5A is a block diagram of a circuit structure that can be used for each of the first memory portion 131 and the second memory portion 132. FIG. 5B and FIG. 5C are schematic perspective views illustrating structure examples of the first memory portion 131 and the second memory portion 132.

The first memory portion 131 and the second memory portion 132 each include a driver circuit layer 40 and a memory layer 60. The memory layer 60 is provided over the driver circuit layer 40. Provision of the memory layer 60 over the driver circuit layer 40 can reduce the area occupied by the memory device 100. When N memory layers 60 are provided over the driver circuit layer 40 as illustrated in FIG. 5B, the memory capacity per unit area of the memory device 100 can be increased.

### <Structure Example of Driver Circuit Layer 40>

The driver circuit layer 40 has a function of writing and reading data to and from the memory layer 60. The driver circuit layer 40 includes a control circuit 41, a write row driver 42, a read row driver 43, a write column driver 44, and a read column driver 45.

In the first memory portion 131 and the second memory portion 132, each circuit, each signal, and each voltage can be appropriately selected as needed. Alternatively, another circuit or another signal may be added. A signal CLK, a signal REST, a signal CE, a signal GW, a signal ADDR, a signal WE, a signal RE, and a signal WD are signals input from the outside, and a signal RD is a signal output to the outside. The signal CLK is a clock signal.

The signal REST, the signal CE, the signal GW, the signal WE, and the signal RE are control signals. The signal REST is a reset signal. The signal CE is a chip enable signal, and the signal GW is a global write enable signal. The signal WE is a write enable signal, and the signal RE is a read enable signal. The signal WD is write data, and the signal RD is read data.

The signal ADDR includes a signal RADDR. The signal WE and the signal RADDR are supplied to the write row driver 42 through a NAND circuit. The signal RE and the signal RADDR are supplied to the read row driver 43 through a NAND circuit. The signal WE is supplied to the write column driver 44, and the signal RE is supplied to the read column driver 45.

The control circuit 41 is a logic circuit having a function of controlling the overall operation of the memory device. For example, the control circuit performs logic operation on the signal CE, the signal GW, and the like to determine an operation mode (e.g., a writing operation or a reading operation) of the memory device. Alternatively, the control circuit 41 generates a control signal for executing the operation mode.

The write row driver 42 is electrically connected to the memory layer 60 through a plurality of wirings WWL. The write row driver 42 has a function of selecting the wiring WWL specified by the control circuit 41.

The read row driver 43 is electrically connected to the memory layer 60 through a plurality of wirings RWL. The read row driver 43 has a function of selecting the wiring RWL specified by the control circuit 41.

The write column driver 44 is electrically connected to the memory layer 60 through a plurality of wirings WBL. The write column driver 44 has a function of selecting the wiring WBL specified by the control circuit 41. The write column driver 44 has a function of writing the signal WD to the memory layer 60.

The read column driver 45 is electrically connected to the memory layer 60 through a plurality of wirings RBL. The read column driver 45 has a function of selecting the wiring RBL specified by the control circuit 41. The read column driver 45 has a function of reading data, which is stored in the memory layer 60, as the signal RD.

### <Structure Example of Memory Layer 60>

A structure example of the memory layer 60 is described. The memory layer 60 includes a memory array 15. The memory array 15 includes a plurality of memory cells 10. FIG. 5A illustrates an example in which the memory array 15 includes the plurality of memory cells 10 arranged in a matrix of m rows and n columns (each of m and n is an integer greater than or equal to 2).

Note that in FIG. 5A and the like, the row direction is the X direction and the column direction is the Y direction. In FIG. 5A, the memory cell 10 provided in the first row and the n-th column is referred to as a memory cell 10[1,n], the memory cell 10 provided in the m-th row and the first column is referred to as a memory cell 10[m,1], and the memory cell 10 provided in the m-th row and the n-th column is referred to as a memory cell 10[m,n].

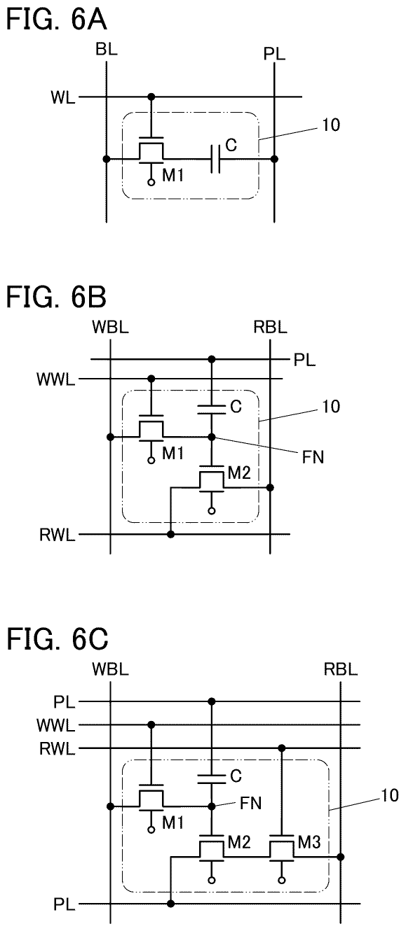

FIG. 6A to FIG. 6C each illustrate a circuit structure example that can be applied to the memory cell 10. FIG. 6A illustrates a circuit structure example of a 1Tr1C memory cell including one transistor and one capacitor. In FIG. 6A, a gate of the transistor M1 is electrically connected to a wiring WL, one of a source and a drain of the transistor M1 is electrically connected to a wiring BL, and the other of the source and the drain of the transistor M1 is electrically connected to one terminal of a capacitor C. The other terminal of the capacitor C is electrically connected to a wiring PL.

FIG. 6B illustrates a circuit structure example of a 2Tr1C memory cell including two transistors and one capacitor. In FIG. 6B, the gate of the transistor M1 is electrically connected to the wiring WWL. One of the source and the drain of the transistor M1 is electrically connected to the wiring WBL. One terminal of the capacitor C is electrically connected to the wiring PL. The other of the source and the drain of the transistor M1 is electrically connected to the other terminal of the capacitor C and a gate of a transistor M2. One of a source and a drain of the transistor M2 is electrically connected to the wiring RWL, and the other of the source and the drain of the transistor M2 is electrically connected to the wiring RBL.

A region always having the same potential where the other of the source and the drain of the transistor M1, the other terminal of the capacitor C, and the gate of the transistor M2 are electrically connected to each other functions as a memory node FN.

FIG. 6C illustrates a circuit structure example of a 3Tr1C memory cell including three transistors and one capacitor. FIG. 6C is a variation of FIG. 6B. Thus, differences between FIG. 6B and FIG. 6C are described here.

In FIG. 6C, one of a source and a drain of the transistor M2 is electrically connected to the wiring PL, and the other is electrically connected to one of a source and a drain of a transistor M3. A gate of the transistor M3 is electrically connected to the wiring RWL, and the other of the source and the drain of the transistor M3 is electrically connected to the wiring RBL.

The wiring WL illustrated in FIG. 6A functions as the wiring WWL and the wiring RWL. The wiring BL functions as the wiring WBL and the wiring RBL. In the circuit structure illustrated in FIG. 6A, the number of wirings electrically connecting the driver circuit layer 40 and the memory layer 60 can be smaller than in the circuit structures illustrated in FIG. 6B and FIG. 6C.

In the circuit structure examples illustrated in FIG. 6A to FIG. 6C, a fixed potential is supplied to the wiring PL. For example, a ground potential (GND) is supplied to the wiring PL. As the transistor M1 to the transistor M3, transistors with back gates may be used. The gate and the back gate are placed such that a channel formation region of a semiconductor is sandwiched between the gate and the back gate. The gate and the back gate are formed using conductors and the back gate can function in a manner similar to that of the gate. By changing the potential of the back gate, the threshold voltage of the transistor can be changed. The potential of the back gate may be the same as the potential of the gate or may be a ground potential or a given potential.

In addition, the gate and the back gate are formed using conductors and thus also have a function of preventing an electric field generated outside the transistor from affecting the semiconductor in which a channel is formed (particularly, a function of preventing static electricity). That is, a variation in the electrical characteristics of the transistor due to the influence of an external electric field such as static electricity can be prevented. By providing the back gate, the amount of change in the threshold voltage of the transistor before and after a reliability test (e.g., a BT (Bias Temperature) stress test) can be reduced.

For example, the use of a transistor with a back gate as the transistor M1 can reduce the influence of an external electric field, allowing the transistor M1 to be maintained in the stable off state. Thus, data written to the memory node FN can be retained stably. The back gate stabilizes the operation of the memory cell 10 and increases the reliability of the memory device including the memory cell 10.

As a semiconductor layer where the channel of the transistor included in the memory cell 10 is formed, a single crystal semiconductor, a polycrystalline semiconductor, a microcrystalline semiconductor, an amorphous semiconductor, or the like can be used alone or in combination. As a semiconductor material, silicon, germanium, or the like can be used, for example. Alternatively, a compound semiconductor such as silicon germanium, silicon carbide, gallium arsenide, oxide semiconductor, or nitride semiconductor may be used.

As the transistor included in the memory cell 10, a transistor including an oxide semiconductor, which is a kind of a metal oxide, in a semiconductor layer where a channel is formed (also referred to as an “OS transistor”) may be used. An oxide semiconductor has a band gap higher than or equal to 2 eV, and thus has an extremely low off-state current. Thus, the power consumption of the memory cell 10 can be reduced. Accordingly, the power consumption of the memory device including the memory cell 10 can be reduced.

A memory cell including an OS transistor can be referred to as an “OS memory”. A memory device including the memory cell can also be referred to as an “OS memory”.

The OS transistor operates stably even in a high-temperature environment and has small fluctuation in characteristics. For example, the off-state current hardly increases even in the high-temperature environment. Specifically, the off-state current hardly increases even at an environmental temperature higher than or equal to room temperature and lower than or equal to 200° C. Furthermore, the on-state current is unlikely to decrease even in a high-temperature environment. Thus, the OS memory can operate stably and have high reliability even in the high-temperature environment.

As described above, it is preferable that the first memory portion 131 storing an information bit be formed using a Si memory and the second memory portion 132 storing a check bit be formed using an OS memory. For example, the first memory portion 131 may be a Si memory such as a DRAM, an SRAM, or a flash memory, and the second memory portion 132 may be an OS memory having any of the circuit structures illustrated in FIG. 6A to FIG. 6C or the like.

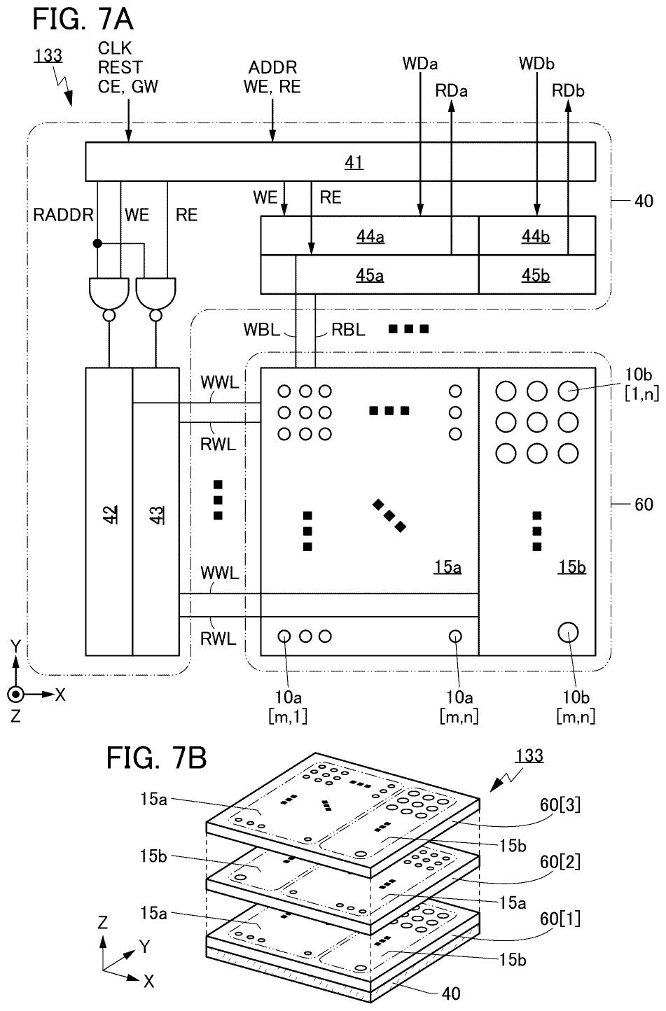

Alternatively, a memory portion 133 including both a Si memory and an OS memory may be used as the memory means 130. FIG. 7A illustrates a structure example of the memory portion 133. The memory layer 60 of the memory portion 133 includes a memory cell array 15a including a memory cell 10a that is a Si memory and a memory cell array 15b including a memory cell 10b that is an OS memory.

In FIG. 7A, the memory cell 10a in the m-th row and the first column and the memory cell 10a in the m-th row and the n-th column that are included in the memory cell array 15a are referred to as a memory cell 10a[m,1] and a memory cell 10a[m,n], respectively. The memory cell 10b in the first row and the n-th column and the memory cell 10b in the m-th row and the n-th column that are included in the memory cell array 15b are referred to as a memory cell 10b[1,n] and a memory cell 10b[m,n], respectively.

As in FIG. 5B, the driver circuit layer 40 and the memory layer 60 may be provided to overlap with each other in the memory portion 133. As in FIG. 5C, the driver circuit layer 40 and N memory layers 60 may be provided to overlap with each other in the memory portion 133. In the case where an information bit is stored in the memory cell array 15a and a check bit is stored in the memory cell array 15b in one memory layer 60, it is preferable that the memory cell array 15a and the memory cell array 15b in one memory layer 60 be not overlap with each other so that MBU is less likely to occur.

Note that as illustrated in FIG. 5C, some or all of the plurality of memory layers 60 that are stacked are illustrated separately in some cases for easy understanding of the stack state of the memory layers 60.

Note that in the case where a pair of an information bit and a check bit is stored in one memory layer 60 as described above, the memory cell array 15a and the memory cell array 15b in different memory layers 60 may overlap with each other. That is, a region may be included where the memory cell array 15a included in the memory layer 60 in the first layer and the memory cell array 15b included in the memory layer 60 in the second layer overlap with each other. FIG. 7B is a schematic perspective view of the memory portion 133 including three memory layers 60 (a memory layer 60[1], a memory layer 60[2], and a memory layer 60[3]) over the driver circuit layer 40.

The driver circuit layer 40 of the memory portion 133 includes a write column driver 44a having a function of writing a signal WDa to the memory cell array 15a and a read column driver 45a having a function of reading data, which is stored in the memory cell array 15a, as a signal RDa. The driver circuit layer 40 of the memory portion 133 includes a write column driver 44b having a function of writing a signal WDb to the memory cell array 15b and a read column driver 45b having a function of reading data, which is stored in the memory cell array 15b, as a signal RDb.

Note that the memory portion 133 is a memory device including a plurality of memory cell arrays using semiconductor materials with different compositions. The use of the memory portion 133 as the memory means 130 can reduce the area occupied by the memory device 100.

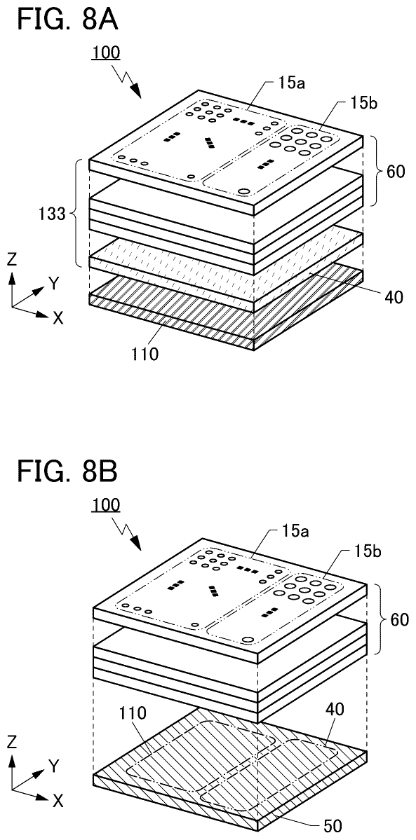

The memory device 100 may be obtained by providing the memory portion 133 over a layer including the control means 110 so that the memory portion 133 overlaps with the layer (see FIG. 8A). Alternatively, the memory device 100 may be obtained by providing the memory layer 60 including the memory cell array 15a and the memory cell array 15b over a layer 50 including the driver circuit layer 40 and the control means 110 so that the memory layer 60 overlaps with the layer 50 (see FIG. 8B). When the control means 110 and the memory means 130 are provided to overlap with each other, the area occupied by the memory device 100 can be reduced.

This embodiment can be implemented in combination with the other embodiments described in this specification as appropriate.

### Embodiment 3

In this embodiment, bit interleaving will be described. The bit interleaving is a method in which configuration bits of one word are not stored in a physical memory successively but are stored in a dispersed manner so as to be hardly influenced by MBU. When not stored in adjacent physical addresses, configuration bits of one word are hardly influenced by a soft error.

<Case where Bit Interleaving is not Performed>

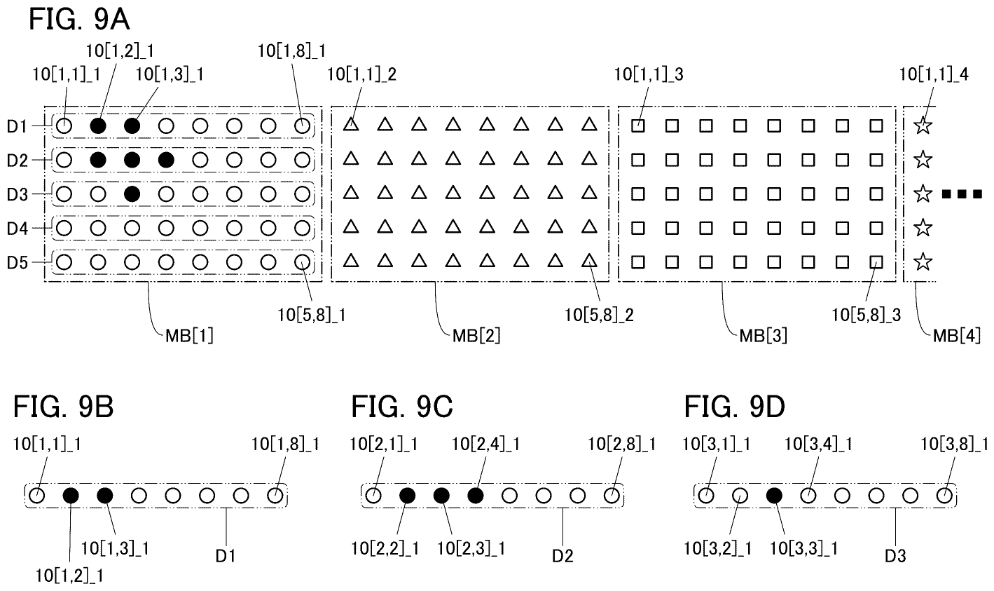

First, the case where 8-bit data is stored without using bit interleaving is described with reference to FIG. 9A to FIG. 9D. FIG. 9A illustrates part of the memory array 15. The memory array 15 is divided into a plurality of memory blocks MB and managed. As an example, FIG. 9A illustrates three memory blocks MB, a memory block MB[1] to a memory block MB[3], and part of a memory block MB[4] that are included in the memory array 15.

FIG. 9A illustrates the case where each of the plurality of memory blocks MB includes 40 memory cells 10 arranged in a matrix of five rows and eight columns. In this embodiment, the memory cells 10 included in the memory block MB[1] are indicated by circles, the memory cells 10 included in the memory block MB[2] are indicated by triangles, the memory cells 10 included in the memory block MB[3] are indicated by rectangles, and the memory cells 10 included in the memory block MB[4] are indicated by stars.

In this embodiment, the memory cell 10 in the first row and the first column included in the memory block MB[1] is referred to as a memory cell 10[1,1]_1, the memory cell 10 in the first row and the eighth column is referred to as a memory cell 10[1,8]_1, and the memory cell 10 in the fifth row and the eighth column is referred to as a memory cell 10[5,8]_1. The memory cell 10 in the first row and the first column included in the memory block MB[2] is referred to as a memory cell 10[1,1]_2, and the memory cell 10 in the fifth row and the eighth column is referred to as a memory cell 10[5,8]_2. The memory cell 10 in the first row and the first column included in the memory block MB[3] is referred to as a memory cell 10[1,1]_3, and the memory cell 10 in the fifth row and the eighth column is referred to as a memory cell 10[5,8]_3. The memory cell 10 in the first row and the first column included in the memory block MB[4] is referred to as a memory cell 10[1,1]_4.

In the memory block MB[1], data D1 is stored in the first row, data D2 is stored in the second row, data D3 is stored in the third row, data D4 is stored in the fourth row, and data D5 is stored in the fifth row.

In this embodiment, soft errors occur in six memory cells 10 included in the memory block MB[1]. Specifically, soft errors occur in a memory cell 10[1,2]_1, a memory cell 10[1,3]_1, a memory cell 10[2,2]_1, a memory cell 10[2,3]_1, a memory cell 10[2,4]_1, and a memory cell 10[3,3]_1. In FIG. 9A and the like, a memory cell in which a soft error occurs is black.

Since the data D1 is stored in the first row of the memory block MB[1] (the memory cell 10[1,1]_1 to the memory cell 10[1,8]_1), soft errors occur in two bits in one word (FIG. 9B). Since the data D2 is stored in the second row of the memory block MB[1] (a memory cell 10[2,1]_1 to a memory cell 10[2,8]_1), soft errors occur in three bits in one word (FIG. 9C). Since the data D3 is stored in the third row of the memory block MB[1] (a memory cell 10[3,1]_1 to a memory cell 10[3,8]_1), a soft error occurs in one bit in one word (FIG. 9D).

That is, MBU occurs in the data D1 and the data D2, and SBU occurs in the data D3. Thus, although the data D3 can be subjected to error correction, the data D1 and the data D2 cannot be subjected to error correction.

<Case where Bit Interleaving is Performed>

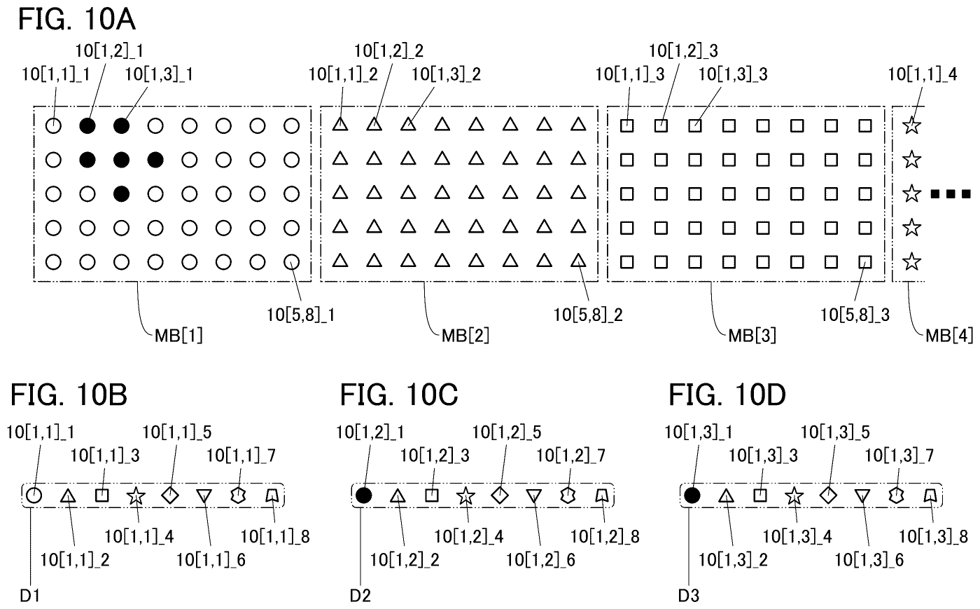

Next, the case where 8-bit data is stored using bit interleaving is described with reference to FIG. 10A to FIG. 10D. FIG. 10A illustrates part of the memory array 15, like FIG. 9A.

In the case where data is stored using bit interleaving, bits included in the data are separately stored in the memory blocks MB. Specifically, the first bit is stored in the memory block MB[1], the second bit is stored in the memory block MB[2], and last, the eighth bit is stored in a memory block MB[8] (not illustrated).

FIG. 10B illustrates a structure example of the data D1 that is divided and stored in eight memory blocks MB. The data D1 is divided and stored in the memory cells 10[1,1] of the eight memory blocks MB. Specifically, configuration bits of the data D1 are stored in the memory cell 10[1,1]_1, the memory cell 10[1,1]_2, the memory cell 10[1,1]_3, the memory cell 10[1,1]_4, a memory cell 10[1,1]_5, a memory cell 10[1,1]_6, a memory cell 10[1,1]_7, and a memory cell 10[1,1]_8.

The data D2 is divided and stored in the memory cells 10[1,2] of the eight memory blocks MB (see FIG. 10C). Specifically, configuration bits of the data D2 is stored in the memory cell 10[1,2]_1, a memory cell 10[1,2]_2, a memory cell 10[1,2]_3, a memory cell 10[1,2]_4, a memory cell 10[1,2]_5, a memory cell 10[1,2]_6, a memory cell 10[1,2]_7, and a memory cell 10[1,2]_8.

The data D3 is divided and stored in the memory cells 10[1,3] of the eight memory blocks MB (see FIG. 10D). Specifically, configuration bits of the data D3 is stored in the memory cell 10[1,3]_1, a memory cell 10[1,3]_2, a memory cell 10[1,3]_3, a memory cell 10[1,3]_4, a memory cell 10[1,3]_5, a memory cell 10[1,3]_6, a memory cell 10[1,3]_7, and a memory cell 10[1,3]_8.

Here, the case where soft errors similar to those in FIG. 9A occur is considered. In the data D1, MBU occurs in the case where bit interleaving is not performed, but no soft error occurs in the case where bit interleaving is performed. In the data D2, MBU occurs in the case where bit interleaving is not performed, but only SBU capable of being subjected to data correction occurs as a soft error in the case where bit interleaving is performed.

By performing bit interleaving as described above, the probability of occurrence of MBU per word can be reduced. Accordingly, a highly reliable memory device can be obtained. Furthermore, an information bit and a check bit forming a hamming code are separately stored in the first memory portion 131 and the second memory portion 132 and bit interleaving is performed in each memory portion, whereby the reliability of the memory device can be further increased.

The bit interleaving may be performed in one or both of the first memory portion 131 and the second memory portion 132. Although the case where configuration bits of one word are stored in different blocks is described in this embodiment, configuration bits of one word may be stored in the same block.

Some of configuration bits of one word may be written to the same block in a dispersed manner. For example, three bits of data whose bit length is 8 bits may be written to the memory block MB[1], and the other five bits may be written to the memory block MB[2] to a memory block MB[6] (not illustrated).

Some of configuration bits of one word may be stored in successive physical addresses. For example, first to third bits of data whose bit length is 8 bits may be stored in successive physical addresses, and fourth to eighth bits may be separately stored (dispersed) in non-successive physical addresses. In this case, a soft error is more likely to occur than in the case where all the configuration bits are stored in a dispersed manner; however, a soft error is less likely to occur and the reliability can be increased compared with the case where all the configuration bits are stored in a physical memory successively.

This embodiment can be implemented in combination with the other embodiments described in this specification as appropriate.

### Embodiment 4

In this embodiment, transistors that can be used in the memory device of one embodiment of the present invention and the like will be described.

### <Structure Example of Transistor>

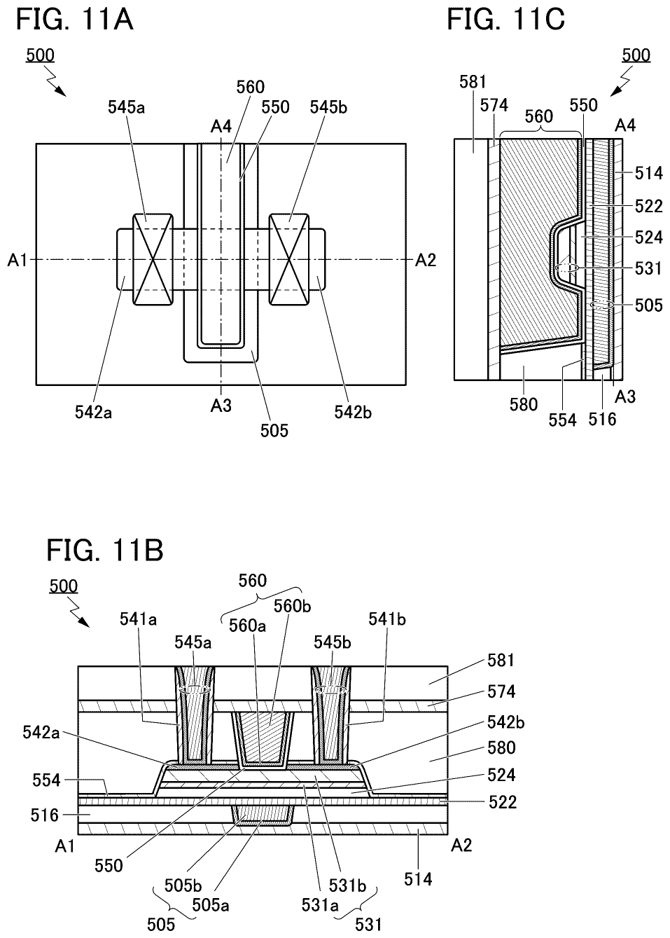

FIG. 11A, FIG. 11B, and FIG. 11C are a top view and cross-sectional views of a transistor 500 that can be used in the memory device of one embodiment of the present invention and the like.

FIG. 11A is the top view of the transistor 500. FIG. 11B and FIG. 11C are the cross-sectional views of the transistor 500. Here, FIG. 11B is a cross-sectional view of a portion indicated by dashed-dotted line A1-A2 in FIG. 11A, and is a cross-sectional view of the transistor 500 in the channel length direction. FIG. 11C is a cross-sectional view of a portion indicated by dashed-dotted line A3-A4 in FIG. 11A, and is a cross-sectional view of the transistor 500 in the channel width direction. Note that for clarity of the drawing, some components are not illustrated in the top view in FIG. 11A.

As illustrated in FIG. 11, the transistor 500 includes a metal oxide 531a placed above a substrate (not illustrated); a metal oxide 531b placed over the metal oxide 531a; a conductor 542a and a conductor 542b that are placed apart from each other over the metal oxide 531b; an insulator 580 that is placed over the conductor 542a and the conductor 542b and has an opening between the conductor 542a and the conductor 542b; a conductor 560 placed in the opening; an insulator 550 placed between the conductor 560 and the metal oxide 531b, the conductor 542a, the conductor 542b, and the insulator 580. Here, as illustrated in FIG. 11B and FIG. 11C, preferably, the top surface of the conductor 560 is substantially level with the top surfaces of the insulator 550 and the insulator 580. Hereinafter, the metal oxide 531a and the metal oxide 531b may be collectively referred to as a metal oxide 531. The conductor 542a and the conductor 542b may be collectively referred to as a conductor 542.

In the transistor 500 illustrated in FIG. 11, the side surfaces of the conductor 542a and the conductor 542b on the conductor 560 side are substantially perpendicular. Note that the angle formed between the side surface and the bottom surface of the conductor 542a or the bottom surface of the conductor 542b may be greater than or equal to 10° and less than or equal to 80°, preferably greater than or equal to 30° and less than or equal to 60°. The side surfaces of the conductor 542a and the conductor 542b that face each other may have a plurality of surfaces. In the transistor 500, two layers of the metal oxide 531a and the metal oxide 531b are stacked in and around a region where a channel is formed (hereinafter, also referred to a channel formation region); however, the present invention is not limited thereto. For example, a single-layer structure of the metal oxide 531b or a stacked-layer structure of three or more layers may be employed. Furthermore, each of the metal oxide 531a and the metal oxide 531b may have a stacked-layer structure of two or more layers.

Here, the conductor 560 functions as a gate electrode of the transistor, and the conductor 542a and the conductor 542b function as a source electrode and a drain electrode. As described above, the conductor 560 is formed to be embedded in the opening of the insulator 580 and the region between the conductor 542a and the conductor 542b. Here, the positions of the conductor 560, the conductor 542a, and the conductor 542b are selected in a self-aligned manner with respect to the opening of the insulator 580. In other words, in the transistor 500, the gate electrode can be placed between the source electrode and the drain electrode in a self-aligned manner. Therefore, the conductor 560 can be formed without an alignment margin, resulting in a reduction in the area occupied by the transistor 500. Accordingly, the display device can have higher resolution. In addition, the display device can have a narrow bezel.

As illustrated in FIG. 11, the conductor 560 preferably includes a conductor 560a provided inside the insulator 550 and a conductor 560b provided to be embedded inside the conductor 560a. Note that in FIG. 11, although the conductor 560 have a stacked-layer structure of two layers, the present invention is not limited thereto. For example, the conductor 560 may have a single-layer structure or a stacked-layer structure of three or more layers.

The transistor 500 preferably includes an insulator 514 placed above the substrate (not illustrated); an insulator 516 placed over the insulator 514; a conductor 505 placed to be embedded in the insulator 516; an insulator 522 placed over the insulator 516 and the conductor 505; and an insulator 524 placed over the insulator 522. The metal oxide 531a is preferably placed over the insulator 524.

As illustrated in FIG. 11, an insulator 554 is preferably placed between the insulator 580 and the insulator 522, the insulator 524, the metal oxide 531a, the metal oxide 531b, the conductor 542a, the conductor 542b, and the insulator 550. Here, as illustrated in FIG. 11B and FIG. 11C, the insulator 554 is preferably in contact with the side surface of the insulator 550, the top surface and side surface of the conductor 542a, the top surface and side surface of the conductor 542b, the side surfaces of the metal oxide 531a, the metal oxide 531b, and the insulator 524 and the top surface of the insulator 522.

An insulator 574 and an insulator 581 functioning as interlayer films are preferably placed over the transistor 500. Here, the insulator 574 is preferably placed in contact with the top surfaces of the conductor 560, the insulator 550, and the insulator 580.

The insulator 522, the insulator 554, and the insulator 574 preferably have a function of inhibiting diffusion of hydrogen (e.g., at least one of a hydrogen atom, a hydrogen molecule, and the like). For example, the insulator 522, the insulator 554, and the insulator 574 preferably have a lower hydrogen permeability than the insulator 524, the insulator 550, and the insulator 580. Moreover, the insulator 522 and the insulator 554 preferably have a function of inhibiting diffusion of oxygen (e.g., at least one of an oxygen atom, an oxygen molecule, and the like). For example, the insulator 522 and the insulator 554 preferably have a lower oxygen permeability than the insulator 524, the insulator 550, and the insulator 580.

A conductor 545 (a conductor 545a and a conductor 545b) that is electrically connected to the transistor 500 and functions as a plug is preferably provided. Note that an insulator 541 (an insulator 541a and an insulator 541b) is provided in contact with the side surface of the conductor 545 functioning as a plug. In other words, the insulator 541 is provided in contact with the inner wall of an opening in the insulator 554, the insulator 580, the insulator 574, and the insulator 581. In addition, a structure may be employed in which a first conductor of the conductor 545 is provided in contact with the side surface of the insulator 541 and a second conductor of the conductor 545 is provided on the inner side of the first conductor. Here, the top surface of the conductor 545 and the top surface of the insulator 581 can be substantially level with each other. Although the transistor 500 has a structure in which the first conductor of the conductor 545 and the second conductor of the conductor 545 are stacked, the present invention is not limited thereto. For example, the conductor 545 may have a single-layer structure or a stacked-layer structure of three or more layers. In the case where a component has a stacked-layer structure, layers may be distinguished by ordinal numbers corresponding to the formation order.

In the transistor 500, a metal oxide functioning as an oxide semiconductor (hereinafter, also referred to as an oxide semiconductor) is preferably used as the metal oxide 531 including the channel formation region (the metal oxide 531a and the metal oxide 531b). For example, it is preferable to use a metal oxide having a band gap of 2 eV or more, preferably 2.5 eV or more as the metal oxide to be the channel formation region of the metal oxide 531.

The metal oxide preferably contains at least indium (In) or zinc (Zn). In particular, indium (In) and zinc (Zn) are preferably contained. In addition to them, an element M is preferably contained. As the element M, one or more of aluminum (Al), gallium (Ga), yttrium (Y), tin (Sn), boron (B), titanium (Ti), iron (Fe), nickel (Ni), germanium (Ge), zirconium (Zr), molybdenum (Mo), lanthanum (La), cerium (Ce), neodymium (Nd), hafnium (Hf), tantalum (Ta), tungsten (W), magnesium (Mg), and cobalt (Co) can be used. In particular, the element M is preferably one or more of aluminum (Al), gallium (Ga), yttrium (Y), and tin (Sn). The element M further preferably contains one or both of Ga and Sn.

The metal oxide 531b in a region that does not overlap with the conductor 542 sometimes has a smaller thickness than the metal oxide 531b in a region that overlaps with the conductor 542. The thin region is formed when part of the top surface of the metal oxide 531b is removed at the time of forming the conductor 542a and the conductor 542b. When a conductive film to be the conductor 542 is formed, a low-resistance region is sometimes formed on the top surface of the metal oxide 531b in the vicinity of the interface with the conductive film. Removing the low-resistance region positioned between the conductor 542a and the conductor 542b on the top surface of the metal oxide 531b in the above manner can prevent formation of the channel in the region.

According to one embodiment of the present invention, a display device that includes small-size transistors and has high resolution can be provided. A display device that includes a transistor with a high on-state current and has high luminance can be provided. A display device that includes a transistor operating at high speed and thus operates at high speed can be provided. A display device that includes a transistor having stable electrical characteristics and is highly reliable can be provided. A display device that includes a transistor with a low off-state current and has low power consumption can be provided.

The structure of the transistor 500 that can be used in the display device of one embodiment of the present invention is described in detail.

The conductor 505 is placed to include a region overlapping with the metal oxide 531 and the conductor 560. Furthermore, the conductor 505 is preferably provided to be embedded in the insulator 516.

The conductor 505 includes a conductor 505a and a conductor 505b. The conductor 505a is provided in contact with the bottom surface and the sidewall of the opening provided in the insulator 516. The conductor 505b is provided to be embedded in a depression portion formed by the conductor 505a. Here, the top surface of the conductor 505b is substantially level with the top surface of the conductor 505a and the top surface of the insulator 516.

The conductor 505a is preferably formed using a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom. Alternatively, the conductor 505a is preferably formed using a conductive material having a function of inhibiting diffusion of oxygen (e.g., at least one of an oxygen atom, an oxygen molecule, and the like).

When a conductive material having a function of inhibiting diffusion of hydrogen is used for the conductor 505a, impurities such as hydrogen contained in the conductor 505b can be inhibited from diffusing into the metal oxide 531 through the insulator 524 and the like. When a conductive material having a function of inhibiting diffusion of oxygen is used for the conductor 505a, the conductivity of the conductor 505b can be inhibited from being lowered because of oxidation. As the conductive material having a function of inhibiting diffusion of oxygen, for example, titanium, titanium nitride, tantalum, tantalum nitride, ruthenium, or ruthenium oxide is preferably used. Thus, the conductor 505a is a single layer or stacked layers of the above conductive materials. For example, titanium nitride is used for the conductor 505a.

The conductor 505b is preferably formed using a conductive material containing tungsten, copper, or aluminum as its main component. For example, tungsten is used for the conductor 505b.

The conductor 560 sometimes functions as a first gate (also referred to as top gate) electrode. The conductor 505 sometimes functions as a second gate (also referred to as bottom gate) electrode. In that case, Vth of the transistor 500 can be controlled by changing a potential applied to the conductor 505 independently of a potential applied to the conductor 560. In particular, by applying a negative potential to the conductor 505, Vth of the transistor 500 can be made higher and the off-state current can be made low. Thus, a drain current at the time when a potential applied to the conductor 560 is 0 V can be lower in the case where a negative potential is applied to the conductor 505 than in the case where a negative potential is not applied to the conductor 505.

The conductor 505 is preferably provided to be larger than the channel formation region in the metal oxide 531. In particular, it is preferable that the conductor 505 extend beyond an end portion of the metal oxide 531 that intersects with the channel width direction, as illustrated in FIG. 11C. In other words, the conductor 505 and the conductor 560 preferably overlap with each other with the insulator therebetween, in a region outside the side surface of the metal oxide 531 in the channel width direction.

With the above structure, the channel formation region of the metal oxide 531 can be electrically surrounded by electric fields of the conductor 560 having a function of the first gate electrode and electric fields of the conductor 505 having a function of the second gate electrode.

The conductor 505 can also function as a wiring. In addition, a conductor functioning as a wiring may be provided below the conductor 505.

The insulator 514 preferably functions as a barrier insulating film that inhibits the entry of impurities such as water or hydrogen to the transistor 500 from the substrate side. Accordingly, it is preferable to use, for the insulator 514, an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (an insulating material through which the impurities are less likely to pass). Alternatively, it is preferable to use an insulating material having a function of inhibiting diffusion of oxygen (e.g., at least one of an oxygen atom, an oxygen molecule, and the like) (an insulating material through which the oxygen is less likely to pass).

For example, aluminum oxide or silicon nitride is preferably used for the insulator 514. Accordingly, it is possible to inhibit diffusion of impurities such as water or hydrogen to the transistor 500 side from the substrate side through the insulator 514. Alternatively, it is possible to inhibit diffusion of oxygen contained in the insulator 524 and the like to the substrate side through the insulator 514.

The permittivity of each of the insulator 516, the insulator 580, and the insulator 581 functioning as an interlayer film is preferably lower than that of the insulator 514. When a material with a low permittivity is used for an interlayer film, the parasitic capacitance generated between wirings can be reduced. For the insulator 516, the insulator 580, and the insulator 581, for example, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, or the like can be used as appropriate.

Note that in this specification and the like, “oxynitride” refers to a material that contains more oxygen than nitrogen. For example, “silicon oxynitride” refers to a material that contains more oxygen than nitrogen and contains silicon as its main component. In this specification and the like, “nitride oxide” refers to a material that contains more nitrogen than oxygen. For example, “aluminum nitride oxide” refers to a material that contains more nitrogen than oxygen and contains aluminum as its main component.

The insulator 522 and the insulator 524 each function as a gate insulator.

Here, the insulator 524 in contact with the metal oxide 531 preferably releases oxygen by heating. In this specification, oxygen that is released by heating is referred to as excess oxygen in some cases. For example, silicon oxide, silicon oxynitride, or the like can be used as appropriate for the insulator 524. When an insulator containing oxygen is provided in contact with the metal oxide 531, oxygen vacancies in the metal oxide 531 can be reduced, leading to improved reliability of the transistor 500.

Specifically, an oxide material that releases part of oxygen by heating is preferably used for the insulator 524. An oxide that releases oxygen by heating is an oxide film in which the amount of released oxygen converted into oxygen atoms is greater than or equal to 1.0×10¹⁸ atoms/cm³, preferably greater than or equal to 1.0×10¹⁹ atoms/cm³, further preferably greater than or equal to 2.0×10¹⁹ atoms/cm³ or greater than or equal to 3.0×10²⁰ atoms/cm³ in TDS (Thermal Desorption Spectroscopy) analysis. Note that the temperature of the film surface in the TDS analysis is preferably within the range of 100° C. to 700° C. or 100° C. to 400° C.

Like the insulator 514 and the like, the insulator 522 preferably functions as a barrier insulating film that inhibits the entry of impurities such as water or hydrogen into the transistor 500 from the substrate side. For example, the insulator 522 preferably has a lower hydrogen permeability than the insulator 524. When the insulator 524, the metal oxide 531, the insulator 550, and the like are surrounded by the insulator 522, the insulator 554, and the insulator 574, the entry of impurities such as water or hydrogen into the transistor 500 from outside can be inhibited.

Furthermore, it is preferable that the insulator 522 have a function of inhibiting diffusion of oxygen (e.g., at least one of an oxygen atom, an oxygen molecule, and the like) (it is preferable that the oxygen be less likely to pass through the insulator 522). For example, the insulator 522 preferably has a lower oxygen permeability than the insulator 524. The insulator 522 preferably has a function of inhibiting diffusion of oxygen and impurities, in which case oxygen contained in the metal oxide 531 is less likely to diffuse to the substrate side. Moreover, the conductor 505 can be inhibited from reacting with oxygen contained in the insulator 524 and the metal oxide 531.

As the insulator 522, an insulator containing an oxide of one or both of aluminum and hafnium, which is an insulating material, is preferably used. As the insulator containing an oxide of one or both of aluminum and hafnium, aluminum oxide, hafnium oxide, an oxide containing aluminum and hafnium (hafnium aluminate), or the like is preferably used. In the case where the insulator 522 is formed using such a material, the insulator 522 functions as a layer inhibiting release of oxygen from the metal oxide 531 and entry of impurities such as hydrogen into the metal oxide 531 from the periphery of the transistor 500.

Alternatively, aluminum oxide, bismuth oxide, germanium oxide, niobium oxide, silicon oxide, titanium oxide, tungsten oxide, yttrium oxide, or zirconium oxide may be added to these insulators, for example. Alternatively, these insulators may be subjected to nitriding treatment. Silicon oxide, silicon oxynitride, or silicon nitride may be stacked over any of the above insulators.

The insulator 522 may be a single layer or a stacked layer using an insulator containing what is called a high-k material, such as aluminum oxide, hafnium oxide, tantalum oxide, zirconium oxide, lead zirconate titanate (PZT), strontium titanate (SrTiO3), or (Ba,Sr) TiO3 (BST). With further miniaturization and higher integration of a transistor, a problem such as generation of leakage current may arise because of a thinned gate insulator. When a high-k material is used for the insulator functioning as a gate insulator, a gate potential at the time of the operation of the transistor can be reduced while the physical thickness is maintained.

Note that the insulator 522 and the insulator 524 may each have a stacked-layer structure of two or more layers. In that case, without limitation to a stacked-layer structure formed of the same material, a stacked-layer structure formed of different materials may be employed. For example, an insulator similar to the insulator 524 may be provided below the insulator 522.

The metal oxide 531 includes the metal oxide 531a and the metal oxide 531b over the metal oxide 531a. When the metal oxide 531a is provided under the metal oxide 531b, it is possible to inhibit diffusion of impurities into the metal oxide 531b from the components formed below the metal oxide 531a.

Note that the metal oxide 531 preferably has a stacked-layer structure of a plurality of oxide layers that differ in the atomic ratio of metal atoms. For example, in the case where the metal oxide 531 contains at least indium (In) and the element M, the proportion of the number of atoms of the element M contained in the metal oxide 531a to the number of atoms of all elements that constitute the metal oxide 531a is preferably higher than the proportion of the number of atoms of the element M contained in the metal oxide 531b to the number of atoms of all elements that constitute the metal oxide 531b. In addition, the atomic ratio of the element M to In in the metal oxide 531a is preferably greater than the atomic ratio of the element M to In in the metal oxide 531b.

The energy of the conduction band minimum of the metal oxide 531a is preferably higher than the energy of the conduction band minimum of the metal oxide 531b. In other words, the electron affinity of the metal oxide 531a is preferably smaller than the electron affinity of the metal oxide 531b.

Here, the energy level of the conduction band minimum gently changes at junction portions between the metal oxide 531a and the metal oxide 531b. In other words, at junction portions between the metal oxide 531a and the metal oxide 531b, the energy level of the conduction band minimum continuously changes or the energy levels are continuously connected. This can be achieved by decreasing the density of defect states in a mixed layer formed at the interface between the metal oxide 531a and the metal oxide 531b.

Specifically, when the metal oxide 531a and the metal oxide 531b contain the same element (as a main component) in addition to oxygen, a mixed layer with a low density of defect states can be formed. For example, an In—Ga—Zn oxide, a Ga—Zn oxide, or gallium oxide may be used as the metal oxide 531a, in the case where the metal oxide 531b is an In—Ga—Zn oxide.

Specifically, as the metal oxide 531a, a metal oxide with In:Ga:Zn=1:3:4[atomic ratio] or 1:1:0.5[atomic ratio] is used. As the metal oxide 531b, a metal oxide with In:Ga:Zn=1:1:1 [atomic ratio], 4:2:3[atomic ratio], or 3:1:2[atomic ratio] is used.

In this case, the metal oxide 531b serves as a main carrier path. When the metal oxide 531a has the above structure, the density of defect states at the interface between the metal oxide 531a and the metal oxide 531b can be made low. Thus, the influence of interface scattering on carrier conduction is small, and the transistor 500 can have high on-state current and high frequency characteristics.

The conductor 542 (the conductor 542a and the conductor 542b) functioning as the source electrode and the drain electrode is provided over the metal oxide 531b. For the conductor 542, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing any of the above metal elements; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen.

When the conductor 542 is provided in contact with the metal oxide 531, the oxygen concentration of the metal oxide 531 in the vicinity of the conductor 542 sometimes decreases. In addition, a metal compound layer that contains the metal contained in the conductor 542 and the component of the metal oxide 531 is sometimes formed in the metal oxide 531 in the vicinity of the conductor 542. In such cases, the carrier concentration of the region in the metal oxide 531 in the vicinity of the conductor 542 increases, and the region becomes a low-resistance region. Here, the region between the conductor 542a and the conductor 542b is formed to overlap with the opening of the insulator 580. Accordingly, the conductor 560 can be placed in a self-aligned manner between the conductor 542a and the conductor 542b.

The insulator 550 functions as a gate insulator. The insulator 550 is preferably positioned in contact with the top surface of the metal oxide 531b. For the insulator 550, silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide can be used. In particular, silicon oxide and silicon oxynitride, which are thermally stable, are preferable.

As in the insulator 524, the concentration of impurities such as water or hydrogen in the insulator 550 is preferably reduced. The thickness of the insulator 550 is preferably greater than or equal to 1 nm and less than or equal to 20 nm.

An insulator may be provided between the insulator 550 and the insulator 580, the insulator 554, the conductor 542, and the metal oxide 531b. For the insulator, aluminum oxide, hafnium oxide, or the like is preferably used. Providing the insulator can inhibit release of oxygen from the metal oxide 531b, excessive supply of oxygen to the metal oxide 531b, oxidation of the conductor 542, and the like.

A metal oxide may be provided between the insulator 550 and the conductor 560. The metal oxide preferably inhibits diffusion of oxygen from the insulator 550 to the conductor 560. Accordingly, oxidation of the conductor 560 due to oxygen in the insulator 550 can be inhibited.

The metal oxide functions as part of the gate insulator in some cases. Therefore, when silicon oxide, silicon oxynitride, or the like is used for the insulator 550, a metal oxide that is a high-k material with a high dielectric constant is preferably used as the metal oxide. When the gate insulator has a stacked-layer structure of the insulator 550 and the metal oxide, the stacked-layer structure can be thermally stable and have a high dielectric constant. Accordingly, a gate potential applied during the operation of the transistor can be reduced while the physical thickness of the gate insulator is maintained. In addition, the equivalent oxide thickness (EOT) of the insulator functioning as the gate insulator can be reduced.

Specifically, a metal oxide containing one kind or two or more kinds selected from hafnium, aluminum, gallium, yttrium, zirconium, tungsten, titanium, tantalum, nickel, germanium, magnesium, and the like can be used. It is particularly preferable to use an insulator containing an oxide of one or both of aluminum and hafnium, such as aluminum oxide, hafnium oxide, or an oxide containing aluminum and hafnium (hafnium aluminate).

Although the conductor 560 has a two-layer structure in FIG. 11, the conductor 560 may have a single-layer structure or a stacked-layer structure of three or more layers.

The conductor 560a is preferably formed using the aforementioned conductor having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom. Alternatively, it is preferable to use a conductive material having a function of inhibiting diffusion of oxygen (e.g., at least one of an oxygen atom, an oxygen molecule, and the like).

When the conductor 560a has a function of inhibiting diffusion of oxygen, it is possible to inhibit a reduction in conductivity of the conductor 560b due to oxidation caused by oxygen contained in the insulator 550. As a conductive material having a function of inhibiting oxygen diffusion, for example, tantalum, tantalum nitride, ruthenium, ruthenium oxide, or the like is preferably used.

The conductor 560b is preferably formed using a conductive material containing tungsten, copper, or aluminum as its main component. Furthermore, the conductor 560 also functions as a wiring and thus is preferably a conductor having high conductivity. For example, a conductive material containing tungsten, copper, or aluminum as its main component can be used. Moreover, the conductor 560b may have a stacked-layer structure, for example, a stacked-layer structure of the above conductive material and titanium or titanium nitride.

As illustrated in FIG. 11A and FIG. 11C, the side surface of the metal oxide 531 is covered with the conductor 560 in a region where the metal oxide 531b does not overlap with the conductor 542, that is, the channel formation region of the metal oxide 531. Accordingly, the electric field of the conductor 560 functioning as the first gate electrode is likely to act on the side surface of the metal oxide 531. Thus, the on-state current of the transistor 500 can be increased and the frequency characteristics can be improved.

The insulator 554, like the insulator 514 and the like, preferably functions as a barrier insulating film that inhibits the entry of impurities such as water or hydrogen into the transistor 500 from the insulator 580 side. For example, the insulator 554 preferably has a lower hydrogen permeability than the insulator 524. Furthermore, as illustrated in FIG. 11B and FIG. 11C, the insulator 554 is preferably in contact with the side surface of the insulator 550, the top surface and side surface of the conductor 542a, the top surface and side surface of the conductor 542b, and the side surfaces of the metal oxide 531a, the metal oxide 531b, and the insulator 524. Such a structure can inhibit the entry of hydrogen contained in the insulator 580 into the metal oxide 531 through the top surfaces or side surfaces of the conductor 542a, the conductor 542b, the metal oxide 531a, the metal oxide 531b, and the insulator 524.

Furthermore, it is preferable that the insulator 554 have a function of inhibiting diffusion of oxygen (e.g., at least one of an oxygen atom, an oxygen molecule, and the like) (it is preferable that the oxygen be less likely to pass through the insulator 554). For example, the insulator 554 preferably has a lower oxygen permeability than the insulator 580 or the insulator 524.

The insulator 554 is preferably formed by a sputtering method. When the insulator 554 is formed by a sputtering method in an oxygen-containing atmosphere, oxygen can be added to the vicinity of a region of the insulator 524 that is in contact with the insulator 554. Thus, oxygen can be supplied from the region to the metal oxide 531 through the insulator 524. Here, with the insulator 554 having a function of inhibiting upward diffusion of oxygen, oxygen can be prevented from diffusing from the metal oxide 531 into the insulator 580. Moreover, with the insulator 522 having a function of inhibiting downward diffusion of oxygen, oxygen can be prevented from diffusing from the metal oxide 531 to the substrate side. In the above manner, oxygen is supplied to the channel formation region of the metal oxide 531. Accordingly, oxygen vacancies in the metal oxide 531 can be reduced, so that the transistor can be prevented from having normally-on characteristics.

As the insulator 554, an insulator containing an oxide of one or both of aluminum and hafnium is preferably formed, for example. Note that as the insulator containing an oxide of one or both of aluminum and hafnium, aluminum oxide, hafnium oxide, an oxide containing aluminum and hafnium (hafnium aluminate), or the like is preferably used.

The insulator 580 is provided over the insulator 524, the metal oxide 531, and the conductor 542 with the insulator 554 therebetween. The insulator 580 preferably includes, for example, silicon oxide, silicon oxynitride, silicon nitride oxide, silicon oxide to which fluorine is added, silicon oxide to which carbon is added, silicon oxide to which carbon and nitrogen are added, or porous silicon oxide. In particular, silicon oxide and silicon oxynitride, which are thermally stable, are preferable. In particular, materials such as silicon oxide, silicon oxynitride, and porous silicon oxide are preferably used, in which case a region containing oxygen to be released by heating can be easily formed.

The concentration of impurities such as water or hydrogen in the insulator 580 is preferably reduced. In addition, the top surface of the insulator 580 may be planarized.

Like the insulator 514 and the like, the insulator 574 preferably functions as a barrier insulating film that inhibits the entry of impurities such as water or hydrogen into the insulator 580 from above. As the insulator 574, for example, the insulator that can be used as the insulator 514, the insulator 554, and the like can be used.

The insulator 581 functioning as an interlayer film is preferably provided over the insulator 574. As in the insulator 524 or the like, the concentration of impurities such as water or hydrogen in the insulator 581 is preferably reduced.

The conductor 545a and the conductor 545b are placed in openings formed in the insulator 581, the insulator 574, the insulator 580, and the insulator 554. The conductor 545a and the conductor 545b are provided to face each other with the conductor 560 therebetween. Note that the top surfaces of the conductor 545a and the conductor 545b may be on the same plane as the top surface of the insulator 581.

The insulator 541a is provided in contact with the inner wall of the opening in the insulator 581, the insulator 574, the insulator 580, and the insulator 554, and the first conductor of the conductor 545a is formed in contact with the side surface of the insulator 541a. The conductor 542a is positioned on at least part of the bottom portion of the opening, and the conductor 545a is in contact with the conductor 542a. Similarly, the insulator 541b is provided in contact with the inner wall of the opening in the insulator 581, the insulator 574, the insulator 580, and the insulator 554, and the first conductor of the conductor 545b is formed in contact with the side surface of the insulator 541b. The conductor 542b is positioned on at least part of the bottom portion of the opening, and the conductor 545b is in contact with the conductor 542b. The conductor 545a and the conductor 545b are preferably formed using a conductive material containing tungsten, copper, or aluminum as its main component. The conductor 545a and the conductor 545b may have a stacked-layer structure.

In the case where the conductor 545 has a stacked-layer structure, the aforementioned conductor having a function of inhibiting diffusion of impurities such as water or hydrogen is preferably used as the conductor in contact with the conductor 542, the insulator 554, the insulator 580, the insulator 574, and the insulator 581. For example, tantalum, tantalum nitride, titanium, titanium nitride, ruthenium, ruthenium oxide, or the like is preferably used. The conductive material having a function of inhibiting diffusion of impurities such as water or hydrogen can be used as a single layer or stacked layers. The use of the conductive material can inhibit oxygen added to the insulator 580 from being absorbed by the conductor 545a and the conductor 545b. Moreover, impurities such as water or hydrogen can be inhibited from entering the metal oxide 531 through the conductor 545a and the conductor 545b from a layer above the insulator 581.

As the insulator 541a and the insulator 541b, for example, the insulator that can be used as the insulator 554 or the like can be used. Since the insulator 541a and the insulator 541b are provided in contact with the insulator 554, impurities such as water or hydrogen in the insulator 580 or the like can be inhibited from entering the metal oxide 531 through the conductor 545a and the conductor 545b. Furthermore, oxygen contained in the insulator 580 can be inhibited from being absorbed by the conductor 545a and the conductor 545b.

Although not illustrated, a conductor functioning as a wiring may be placed in contact with the top surface of the conductor 545a and the top surface of the conductor 545b. For the conductor functioning as a wiring, a conductive material containing tungsten, copper, or aluminum as its main component is preferably used. Furthermore, the conductor may have a stacked-layer structure and may be a stack of titanium or titanium nitride and the above conductive material, for example. The conductor may be formed to be embedded in an opening provided in an insulator.

### <Materials for Transistor>

Materials that can be used for the transistor will be described.

### [Substrate]

As a substrate where the transistor 500 is formed, an insulator substrate, a semiconductor substrate, or a conductor substrate is used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon, germanium, or the like and a compound semiconductor substrate of silicon carbide, silicon germanium, gallium arsenide, indium phosphide, zinc oxide, or gallium oxide. Another example is a semiconductor substrate in which an insulator region is included in the semiconductor substrate, e.g., an SOI (Silicon On Insulator) substrate. Examples of the conductor substrate include a graphite substrate, a metal substrate, an alloy substrate, and a conductive resin substrate. Other examples include a substrate including a metal nitride and a substrate including a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the elements provided for the substrates include a capacitor, a resistor, a switching element, a light-emitting element, and a memory element.

### [Insulator]

Examples of an insulator include an oxide, a nitride, an oxynitride, a nitride oxide, a metal oxide, a metal oxynitride, and a metal nitride oxide, each of which has an insulating property.

With further miniaturization and higher integration of a transistor, for example, a problem such as generation of leakage current may arise because of a thinned gate insulator. When a high-k material is used for the insulator functioning as a gate insulator, the voltage at the time of the operation of the transistor can be reduced while the physical thickness is maintained. By contrast, when a material with a low dielectric constant is used for the insulator functioning as an interlayer film, the parasitic capacitance generated between wirings can be reduced. Thus, a material is preferably selected depending on the function of an insulator.

Examples of the insulator having a high dielectric constant include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator having a low dielectric constant include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

When a transistor including an oxide semiconductor is surrounded by insulators having a function of inhibiting the passage of oxygen and impurities such as hydrogen (e.g., the insulator 514, the insulator 522, the insulator 554, and the insulator 574), the electrical characteristics of the transistor can be stable. An insulator having a function of inhibiting the passage of oxygen and impurities such as hydrogen can be formed to have a single layer or a stacked layer including an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. Specifically, as the insulator having a function of inhibiting the passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide or a metal nitride such as aluminum nitride, aluminum titanium nitride, titanium nitride, silicon nitride oxide, or silicon nitride can be used.

An insulator functioning as a gate insulator is preferably an insulator including a region containing oxygen to be released by heating. For example, when a structure is employed in which silicon oxide or silicon oxynitride that includes a region containing oxygen to be released by heating is provided in contact with the metal oxide 531, oxygen vacancies included in the metal oxide 531 can be compensated for.

### [Conductor]

For a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen. A semiconductor having high electrical conductivity, typified by polycrystalline silicon containing an impurity element such as phosphorus, or silicide such as nickel silicide may be used.

A plurality of conductors formed using any of the above materials may be stacked. For example, a stacked-layer structure combining a material containing the above metal element and a conductive material containing oxygen may be employed. In addition, a stacked-layer structure combining a material containing the above metal element and a conductive material containing nitrogen may be employed. Furthermore, a stacked-layer structure combining a material containing the above metal element, a conductive material containing oxygen, and a conductive material containing nitrogen may be employed.

In the case where a metal oxide is used for the channel formation region of the transistor, the conductor functioning as the gate electrode preferably has a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. Indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

At least part of this embodiment can be implemented in combination with the other embodiments described in this specification as appropriate.

The structure described in this embodiment can be used in an appropriate combination with the structures described in the other embodiments.

### Embodiment 5

Described in this embodiment is a metal oxide (hereinafter, also referred to as an oxide semiconductor) that can be used in the OS transistor described in the above embodiment.

The metal oxide used in the OS transistor preferably contains at least indium or zinc, and further preferably contains indium and zinc. The metal oxide preferably contains indium, M (M is one or more kinds selected from gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example. In particular, M is preferably one or more kinds selected from gallium, aluminum, yttrium, and tin, and M is further preferably gallium.

The metal oxide can be formed by a sputtering method, a chemical vapor deposition (CVD) method such as a metal organic chemical vapor deposition (MOCVD) method, an atomic layer deposition (ALD) method, or the like.

Hereinafter, an oxide containing indium (In), gallium (Ga), and zinc (Zn) is described as an example of the metal oxide. Note that an oxide containing indium (In), gallium (Ga), and zinc (Zn) may be referred to as an In—Ga—Zn oxide.

### <Classification of Crystal Structure>

Amorphous (including completely amorphous), CAAC (c-axis-aligned crystalline), nc (nanocrystalline), CAC (cloud-aligned composite), single crystal, and polycrystalline (poly crystal) can be given as examples of a crystal structure of an oxide semiconductor.

Note that a crystal structure of a film or a substrate can be evaluated with an X-ray diffraction (XRD) spectrum. For example, evaluation is possible using an XRD spectrum that is obtained by GIXD (Grazing-Incidence XRD) measurement. Note that a GIXD method is also referred to as a thin film method or a Seemann-Bohlin method. Hereinafter, an XRD spectrum obtained from GIXD measurement is simply referred to as an XRD spectrum in some cases.

For example, the XRD spectrum of a quartz glass substrate shows a peak with a substantially bilaterally symmetrical shape. On the other hand, the peak of the XRD spectrum of the In—Ga—Zn oxide film having a crystal structure has a bilaterally asymmetrical shape. The asymmetrical peak of the XRD spectrum clearly shows the existence of a crystal in the film or the substrate. In other words, the film or the substrate cannot be regarded as being in an amorphous state unless it has a bilaterally symmetrical peak in the XRD spectrum.

A crystal structure of a film or a substrate can also be evaluated with a diffraction pattern obtained by a nanobeam electron diffraction (NBED) method (such a pattern is also referred to as a nanobeam electron diffraction pattern). For example, a halo pattern is observed in the diffraction pattern of a quartz glass substrate, which indicates that the quartz glass substrate is in an amorphous state. Furthermore, not a halo pattern but a spot-like pattern is observed in the diffraction pattern of an In—Ga—Zn oxide film formed at room temperature. This suggests that the In—Ga—Zn oxide film formed at room temperature is in an intermediate state, which is neither a single crystal nor polycrystal nor an amorphous state, and it cannot be concluded that the In—Ga—Zn oxide film is in an amorphous state.

[Structure of oxide semiconductor]

Note that oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductors include a CAAC-OS (C-Axis Aligned Crystalline Oxide Semiconductor), an nc-OS (nanocrystalline Oxide Semiconductor), and a CAC-OS (Cloud-Aligned Composite Oxide Semiconductor). Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, a-like OS, and CAC-OS are described in detail.

### [CAAC-OS]

The CAAC-OS is an oxide semiconductor that has a plurality of crystal regions each of which has c-axis alignment in a particular direction. Note that the particular direction refers to the film thickness direction of a CAAC-OS film, the normal direction of the surface where the CAAC-OS film is formed, or the normal direction of the surface of the CAAC-OS film. The crystal region refers to a region having a periodic atomic arrangement. Note that when an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the orientation of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one minute crystal, the maximum diameter of the crystal region is less than 10 nm. In the case where the crystal region is formed of a large number of fine crystals, the maximum diameter of the crystal region may be approximately several tens of nanometers.

In the case of an In—Ga—Zn oxide, the CAAC-OS tends to have a layered crystal structure (also referred to as a layered structure) in which a layer containing indium (In) and oxygen (hereinafter, an In layer) and a layer containing gallium (Ga), zinc (Zn), and oxygen (hereinafter, a (Ga,Zn) layer) are stacked. Indium and gallium can be replaced with each other. Therefore, indium may be contained in the (Ga,Zn) layer. In addition, gallium may be contained in the In layer. Note that zinc may be contained in the In layer. Such a layered structure is observed as a lattice image in a high-resolution TEM (Transmission Electron Microscope) image, for example.

When the CAAC-OS film is subjected to structural analysis by Out-of-plane XRD measurement with an XRD apparatus using θ/2θ scanning, for example, a peak indicating c-axis alignment is detected at or around 2θ of 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of an incident electron beam passing through a sample (also referred to as a direct spot) as a symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear crystal grain boundary (grain boundary) cannot be observed even in the vicinity of the distortion in the CAAC-OS. That is, formation of a crystal grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

A crystal structure where a clear crystal grain boundary is observed is what is called polycrystal. It is highly probable that the crystal grain boundary becomes a recombination center and captures carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a crystal grain boundary as compared with an In oxide.

The CAAC-OS is an oxide semiconductor with high crystallinity in which no clear crystal grain boundary is observed. Thus, in the CAAC-OS, a reduction in electron mobility due to the crystal grain boundary is unlikely to occur. Moreover, since the crystallinity of an oxide semiconductor might be decreased by entry of impurities, formation of defects, and/or the like, the CAAC-OS can be regarded as an oxide semiconductor that has small amounts of impurities and defects (e.g., oxygen vacancies). Thus, an oxide semiconductor including the CAAC-OS is physically stable. Therefore, the oxide semiconductor including the CAAC-OS is resistant to heat and has high reliability. In addition, the CAAC-OS is stable with respect to high temperatures in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a minute crystal. Note that the size of the minute crystal is, for example, greater than or equal to 1 nm and less than or equal to 10 nm, particularly greater than or equal to 1 nm and less than or equal to 3 nm; thus, the minute crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis by out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter greater than the diameter of a nanocrystal (e.g., greater than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or less than the diameter of a nanocrystal (e.g., greater than or equal to 1 nm and less than or equal to 30 nm).

[a-like OS]

The a-like OS is an oxide semiconductor having a structure between those of the nc-OS and the amorphous oxide semiconductor. The a-like OS includes a void or a low-density region. That is, the a-like OS has lower crystallinity than the nc-OS and the CAAC-OS. Moreover, the a-like OS has a higher hydrogen concentration in the film than the nc-OS and the CAAC-OS.

### [Structure of Oxide Semiconductor]

Next, a CAC-OS will be described. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state where one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic proportions of In, Ga, and Zn in the metal elements contained in the CAC-OS in an In—Ga—Zn oxide are denoted by [In], [Ga], and [Zn], respectively. For example, the first region in the CAC-OS in the In—Ga—Zn oxide is a region having [In] higher than [In] in the composition of the CAC-OS film. Moreover, the second region is a region having [Ga] higher than [Ga] in the composition of the CAC-OS film. For example, the first region is a region having [In] higher than [In] in the second region and [Ga] lower than [Ga] in the second region. Moreover, the second region is a region having [Ga] higher than [Ga] in the first region and [In] lower than [In] in the first region.

Specifically, the first region is a region containing indium oxide, indium zinc oxide, or the like as its main component. The second region is a region containing gallium oxide, gallium zinc oxide, or the like as its main component. That is, the first region can be rephrased as a region containing In as its main component. The second region can be rephrased as a region containing Ga as its main component.

Note that a clear boundary between the first region and the second region cannot be observed in some cases.

In addition, in a material composition of a CAC-OS in an In—Ga—Zn oxide that contains In, Ga, Zn, and O, there are regions containing Ga as a main component in part of the CAC-OS and regions containing In as a main component in another part of the CAC-OS. These regions each form a mosaic pattern and are randomly present. Thus, it is suggested that the CAC-OS has a structure where metal elements are unevenly distributed.

The CAC-OS can be formed by a sputtering method under a condition where intentional heating is not performed on a substrate, for example. Moreover, in the case of forming the CAC-OS by a sputtering method, any one or more selected from an inert gas (typically, argon), an oxygen gas, and a nitrogen gas are used as a deposition gas. The proportion of the flow rate of an oxygen gas in the total flow rate of the deposition gas during deposition is preferably as low as possible. For example, the proportion of the flow rate of an oxygen gas in the total flow rate of the deposition gas is preferably higher than or equal to 0% and lower than 30%, further preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide has a structure where the region containing In as its main component (the first region) and the region containing Ga as its main component (the second region) are unevenly distributed and mixed.

Here, the first region is a region having higher conductivity than the second region. In other words, when carriers flow through the first region, the conductivity of a metal oxide is exhibited. Accordingly, when the first regions are distributed in a metal oxide like a cloud, high field-effect mobility (u) can be achieved.

The second region is a region having a higher insulating property than the first region. In other words, when the second regions are distributed in a metal oxide, leakage current can be inhibited.

Thus, in the case where a CAC-OS is used for a transistor, by the complementary action of the conductivity due to the first region and the insulating property due to the second region, the CAC-OS can have a switching function (On/Off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current (Iₒₙ), high field-effect mobility (μ), and excellent switching operation can be achieved.

A transistor using the CAC-OS has high reliability. Thus, the CAC-OS is most suitable for a variety of semiconductor devices such as a display device.

An oxide semiconductor has various structures with different properties. Two or more kinds among an amorphous oxide semiconductor, a polycrystalline oxide semiconductor, an a-like OS, a CAC-OS, an nc-OS, and a CAAC-OS may be included in an oxide semiconductor of one embodiment of the present invention.

### <Transistor Including Oxide Semiconductor>

Next, the case where the above oxide semiconductor is used for a transistor will be described.

When the above oxide semiconductor is used for a transistor, a transistor with high field-effect mobility can be achieved. In addition, a transistor with high reliability can be achieved.

It is particularly preferable to use an oxide containing indium (In), gallium (Ga), and zinc (Zn) (also referred to as “IGZO”) for a semiconductor layer where a channel is formed. Alternatively, an oxide containing indium (In), aluminum (Al), and zinc (Zn) (also referred to as “IAZO”) may be used for the semiconductor layer. Alternatively, an oxide containing indium (In), aluminum (Al), gallium (Ga), and zinc (Zn) (also referred to as “IAGZO”) may be used for the semiconductor layer.

An oxide semiconductor having a low carrier concentration is preferably used for a transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×1011 cm⁻³, yet further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state.

Note that an oxide semiconductor having a low carrier concentration may be referred to as a highly purified intrinsic or substantially highly purified intrinsic oxide semiconductor. A highly purified intrinsic or substantially highly purified intrinsic oxide semiconductor film has a low density of defect states and accordingly has a low density of trap states in some cases.

Charges trapped by the trap states in an oxide semiconductor take a long time to be released and may behave like fixed charges. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon. Note that an impurity in an oxide semiconductor refers to, for example, elements other than the main components of the oxide semiconductor. For example, an element with a concentration lower than 0.1 atomic % can be regarded as an impurity.

### <Impurity>

Here, the influence of each impurity in the oxide semiconductor will be described.

When silicon or carbon, which is one of Group 14 elements, is contained in the oxide semiconductor, defect states are formed in the oxide semiconductor. Thus, the concentration of silicon or carbon (the concentration obtained by secondary ion mass spectrometry (SIMS)) in the oxide semiconductor is set lower than or equal to 2×10¹⁸ atoms/cm³, preferably lower than or equal to 2× 1017 atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the oxide semiconductor, which is obtained by SIMS, is set lower than or equal to 1×10¹⁸ atoms/cm³, preferably lower than or equal to 2× 1016 atoms/cm³.

An oxide semiconductor containing nitrogen easily becomes n-type by generation of electrons serving as carriers and an increase in carrier concentration. As a result, a transistor using an oxide semiconductor that contains nitrogen as a semiconductor is likely to have normally-on characteristics. When nitrogen is contained in the oxide semiconductor, trap states are sometimes formed. This might make the electrical characteristics of the transistor unstable. Therefore, the concentration of nitrogen in the oxide semiconductor, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in an oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor that contains hydrogen is likely to have normally-on characteristics. For this reason, hydrogen in the oxide semiconductor is preferably reduced as much as possible. Specifically, the concentration of hydrogen in the oxide semiconductor, which is measured by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, stable electrical characteristics can be given.

The structures described in this embodiment can be used in an appropriate combination with the structures described in the other embodiments.

### Embodiment 6

In this embodiment, a cross-sectional structure example of the first memory portion 131, the second memory portion 132, and the memory portion 133 is described. Note that this embodiment can also be applied to the memory device 100 illustrated in FIG. 8B by replacing the driver circuit layer 40 with the layer 50.

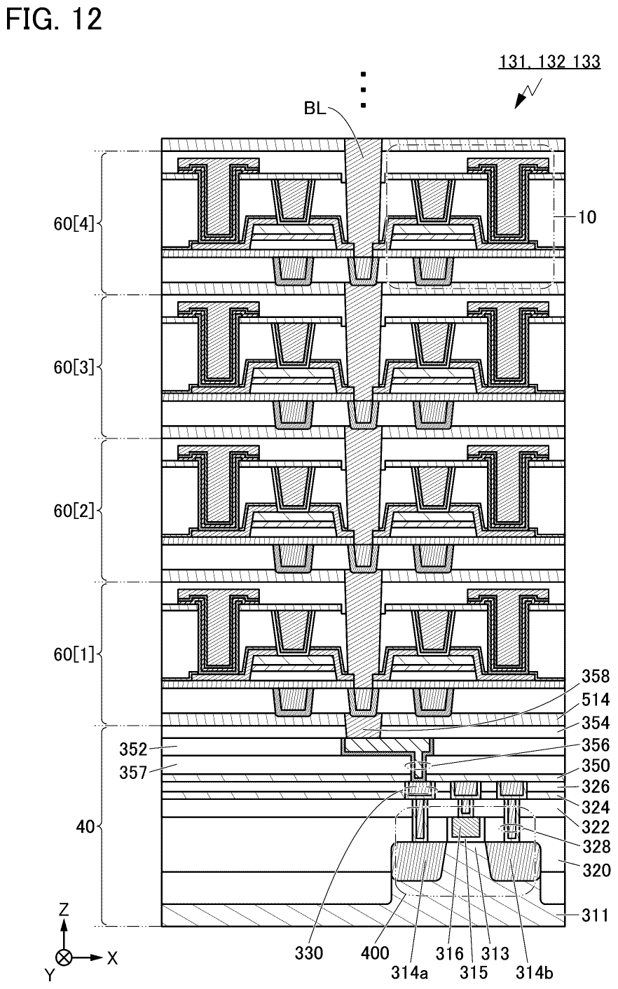

FIG. 12 illustrates a cross-sectional structure example of the first memory portion 131, the second memory portion 132, and the memory portion 133 in the case where the 1Tr1C circuit structure illustrated in FIG. 6A is used for the memory cell 10. Note that the cross-sectional structure example illustrated in FIG. 12 corresponds to part of the first memory portion 131, part of the second memory portion 132, or part of the memory portion 133. In the example illustrated in FIG. 12, the memory layer 60[1] to a memory layer 60[4] are stacked over the driver circuit layer 40.

FIG. 12 illustrates a transistor 400 included in the driver circuit layer 40 as an example. The transistor 400 is provided on a substrate 311 and includes a conductor 316 functioning as a gate, an insulator 315 functioning as a gate insulator, a semiconductor region 313 including part of the substrate 311, and a low-resistance region 314a and a low-resistance region 314b functioning as a source region and a drain region. The transistor 400 may be a p-channel transistor or an n-channel transistor. As the substrate 311, a single crystal silicon substrate can be used, for example.

Here, in the transistor 400 illustrated in FIG. 12, the semiconductor region 313 (part of the substrate 311) where a channel is formed has a protruding shape. Furthermore, the conductor 316 is provided to cover the side surface and the top surface of the semiconductor region 313 with the insulator 315 therebetween (not illustrated). Note that a material for adjusting the work function may be used as the conductor 316. Such a transistor 400 is also referred to as a FIN-type transistor because it utilizes a protruding portion of a semiconductor substrate. Note that an insulator functioning as a mask for forming the protruding portion may be included in contact with an upper portion of the protruding portion. Furthermore, although the case where the protruding portion is formed by processing part of the semiconductor substrate is described here, a semiconductor film having a protruding shape may be formed by processing an SOI (Silicon on Insulator) substrate.

Note that the transistor 400 illustrated in FIG. 12 is an example and the structure is not limited thereto; an appropriate transistor can be used in accordance with a circuit structure or a driving method.

A wiring layer provided with an interlayer film, a wiring, a plug, and the like may be provided between the driver circuit layer 40 and the memory layers 60 or between a k-th memory layer 60 and a (k+1)-th memory layer 60. In this embodiment and the like, the k-th memory layer 60 is referred to as a memory layer 60[k], and the (k+1)-th memory layer 60 is referred to as a memory layer 60[k+1], in some cases. Here, k is an integer greater than or equal to 1 and less than or equal to N. In this embodiment and the like, the solutions of “k+α (α is an integer greater than or equal to 1)” and “k−α” are each an integer greater than or equal to 1 and less than or equal to N.

A plurality of wiring layers can be provided in accordance with design. Furthermore, in this specification and the like, a wiring and a plug electrically connected to the wiring may be a single component. That is, there are cases where part of a conductor functions as a wiring and part of a conductor functions as a plug.

For example, an insulator 320, an insulator 322, an insulator 324, and an insulator 326 are sequentially stacked over the transistor 400 as interlayer films. A conductor 328 or the like is embedded in the insulator 320 and the insulator 322. A conductor 330 or the like is embedded in the insulator 324 and the insulator 326. Note that the conductor 328 and the conductor 330 each function as a contact plug or a wiring.

The insulators functioning as the interlayer film may also function as a planarization film that covers an uneven shape thereunder. For example, the top surface of the insulator 320 may be planarized by planarization treatment using a chemical mechanical polishing (CMP) method or the like to increase the level of planarity.

A wiring layer may be provided over the insulator 326 and the conductor 330. For example, in FIG. 12, an insulator 350, an insulator 357, an insulator 352, and an insulator 354 are stacked in this order over the insulator 326 and the conductor 330. A conductor 356 is formed in the insulator 350, the insulator 357, and the insulator 352. The conductor 356 functions as a contact plug or a wiring.

Over the insulator 354, the insulator 514 included in the memory layer 60[1] is provided. A conductor 358 is embedded in the insulator 514 and the insulator 354. The conductor 358 functions as a contact plug or a wiring. For example, the wiring BL and the transistor 400 are electrically connected to each other through the conductor 358, the conductor 356, the conductor 330, and the like.

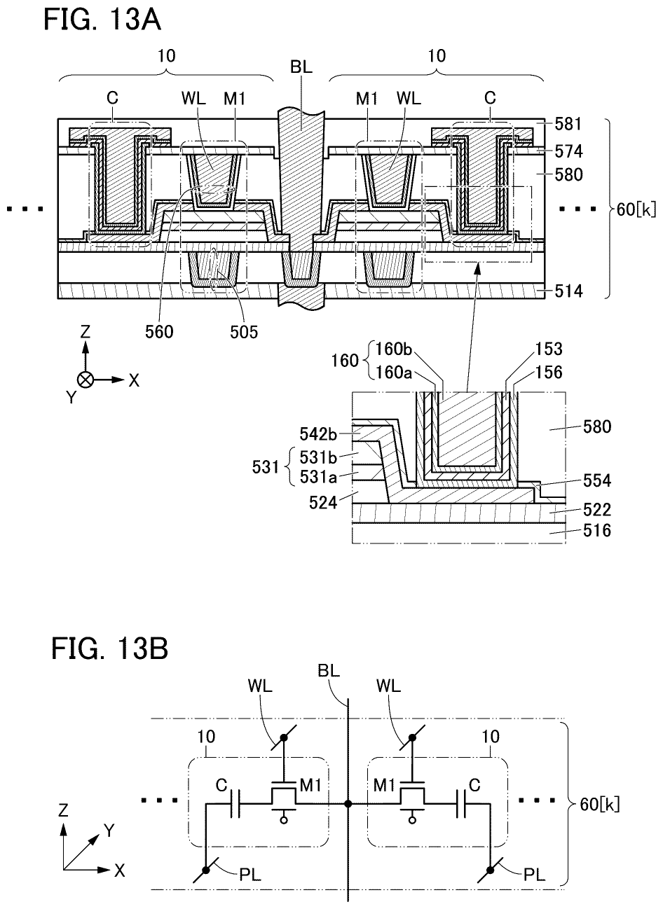

FIG. 13A illustrates a cross-sectional structure example of the memory layer 60[k]. FIG. 13B is an equivalent circuit diagram of FIG. 13A. FIG. 13A illustrates an example where two memory cells 10 are electrically connected to one wiring BL.

The memory cell 10 illustrated in FIG. 12 and FIG. 13A includes the transistor M1 and the capacitor C. As the transistor M1, the transistor 500 described in the above embodiment can be used.

In this embodiment, a variation of the transistor 500 is illustrated as the transistor M1. Specifically, the transistor M1 is different from the transistor 500 in that the conductor 542a and the conductor 542b extend beyond an edge of the metal oxide 531.

The memory cell 10 illustrated in FIG. 12 and FIG. 13A includes a conductor 156 functioning as one terminal of the capacitor C, an insulator 153 functioning as a dielectric, and a conductor 160 (a conductor 160a and a conductor 160b) functioning as the other terminal of the capacitor C. The conductor 156 is electrically connected to part of the conductor 542b. The conductor 160 is electrically connected to the wiring PL (not illustrated in FIG. 13A).

The capacitor C is formed in an opening portion that is provided by removal of part of the insulator 574, part of the insulator 580, and part of the insulator 554. Since the conductor 156, the insulator 580, and the insulator 554 are formed along a side surface of the opening portion, the conductor 156, the insulator 580, and the insulator 554 are preferably formed by an ALD method, a CVD method, or the like.

The conductor 156 and the conductor 160 may be formed using a conductor that can be used for the conductor 505 or the conductor 560. For example, the conductor 156 may be formed using titanium nitride by an ALD method. The conductor 160a may be formed using titanium nitride by an ALD method, and the conductor 160b may be formed using tungsten by a CVD method. Note that in the case where the adhesion of tungsten to the insulator 153 is sufficiently high, a single-layer film of tungsten formed by a CVD method may be used as the conductor 160.

For the insulator 153, an insulator of a high dielectric constant (high-k) material (material with a high relative permittivity) is preferably used. As the insulator of the high dielectric constant material, an oxide, an oxynitride, a nitride oxide, or a nitride containing one or more kinds of metal element selected from aluminum, hafnium, zirconium, gallium, and the like can be used, for example. The above-described oxide, oxynitride, nitride oxide, and nitride may contain silicon. Insulating layers each formed of any of the above-described materials can be stacked to be used.

As the insulator of the high dielectric constant material, aluminum oxide, hafnium oxide, zirconium oxide, an oxide containing aluminum and hafnium, an oxynitride containing aluminum and hafnium, an oxide containing silicon and hafnium, an oxynitride containing silicon and hafnium, an oxide containing silicon and zirconium, an oxynitride containing silicon and zirconium, an oxide containing hafnium and zirconium, an oxynitride containing hafnium and zirconium, or the like can be used, for example. Using such a high dielectric constant material allows the insulator 153 to be thick enough to inhibit a leakage current and a sufficiently high capacitance of the capacitor C to be ensured.

It is preferable to use stacked insulating layers each formed of any of the above-described materials. A stacked-layer structure using a high dielectric constant material and a material having higher dielectric strength than the high dielectric constant material is preferably used. For example, as the insulator 153, an insulating film in which zirconium oxide, aluminum oxide, and zirconium oxide are stacked in this order can be used. An insulating film in which zirconium oxide, aluminum oxide, zirconium oxide, and aluminum oxide are stacked in this order can be used, for example. As another example, an insulating film in which hafnium zirconium oxide, aluminum oxide, hafnium zirconium oxide, and aluminum oxide are stacked in this order can be used. The stacking of such an insulator having relatively high dielectric strength, such as aluminum oxide, can increase the dielectric strength and inhibit electrostatic breakdown of the capacitor C.

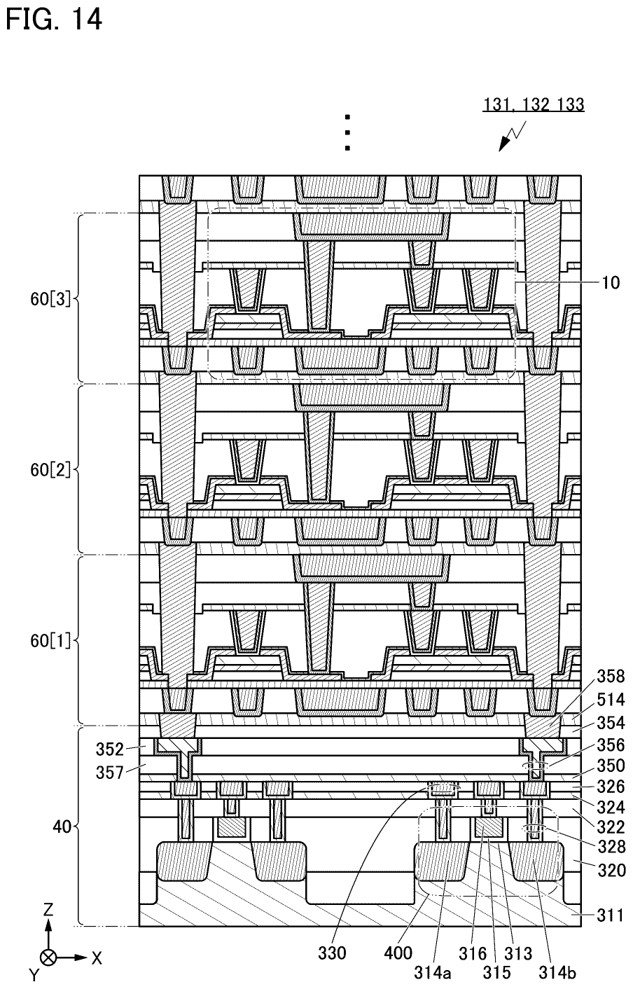

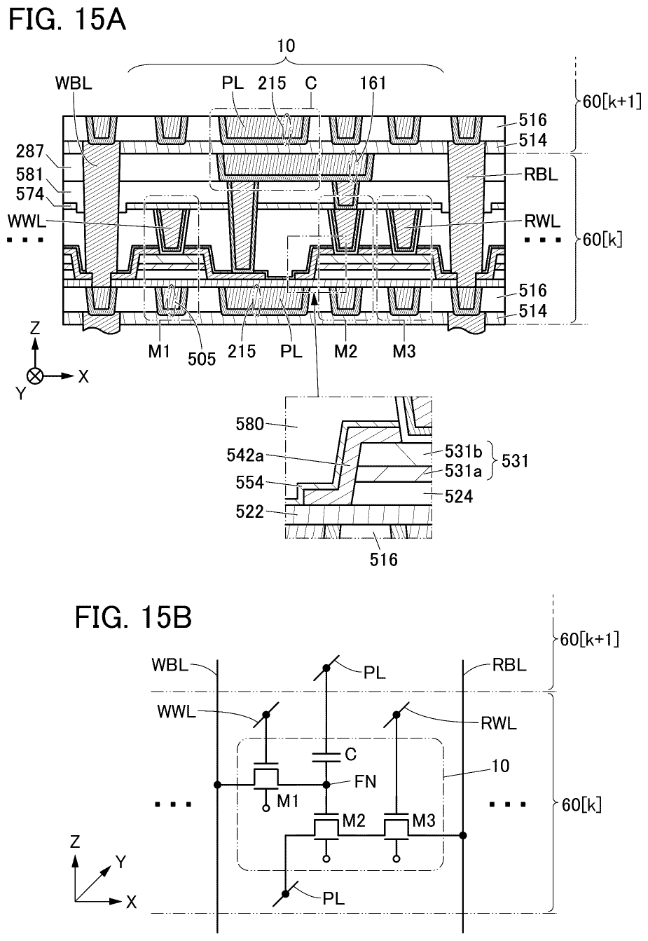

FIG. 14 illustrates a cross-sectional structure example of the first memory portion 131, the second memory portion 132, and the memory portion 133 in the case where the 3Tr1C circuit structure illustrated in FIG. 6C is used for the memory cell 10. FIG. 14 is also a variation of FIG. 12. Thus, the structure of FIG. 14, which is different from that in FIG. 12, is described here. FIG. 15A illustrates a cross-sectional structure example of the memory layer 60[k] in FIG. 14. FIG. 15B is an equivalent circuit diagram of FIG. 15A.

The memory cell 10 illustrated in FIG. 14 and FIG. 15A includes the transistor M1, the transistor M2, and the transistor M3 over the insulator 514. A conductor 215 is provided over the insulator 514. The conductor 215 can be formed using the same material in the same process as those of the conductor 505 at the same time.

The transistor M1, the transistor M2, and the transistor M3 illustrated in FIG. 14 and FIG. 15A can each have a structure similar to that of the transistor M1 illustrated in FIG. 12 and FIG. 13A. Note that FIG. 14 and FIG. 15A illustrate a structure example in which one island-shaped metal oxide 531 is shared by the transistor M2 and the transistor M3. In other words, a part of the one island-shaped metal oxide 531 functions as a channel formation region of the transistor M2, and another part thereof functions as a channel formation region of the transistor M3. Furthermore, the source of the transistor M2 and the drain of the transistor M3 are shared, or the drain of the transistor M2 and the source of the transistor M3 are shared. Thus, the area occupied by the transistor M2 and the transistor M3 is smaller than that of the case where the transistor M2 and the transistor M3 are independently provided.

In the memory cell 10 illustrated in FIG. 14 and FIG. 15A, an insulator 287 is provided over the insulator 581, and a conductor 161 is embedded in the insulator 287. The insulator 514 of the memory layer 60[k+1] is provided over the insulator 287 and the conductor 161.

In FIG. 14 and FIG. 15A, the conductor 215 of the memory layer 60[k+1] functions as one terminal of the capacitor C, the insulator 514 of the memory layer 60[k+1] functions as a dielectric of the capacitor C, and the conductor 161 functions as the other terminal of the capacitor C. The other of the source and the drain of the transistor M1 is electrically connected to the conductor 161 through a contact plug, and the gate of the transistor M2 is electrically connected to the conductor 161 through another contact plug.

This embodiment can be implemented in combination with the other embodiments described in this specification as appropriate.

### Embodiment 7

In this embodiment, examples of an electronic component that includes the memory device 100 described in the above embodiments are described.

### <Electronic Component>

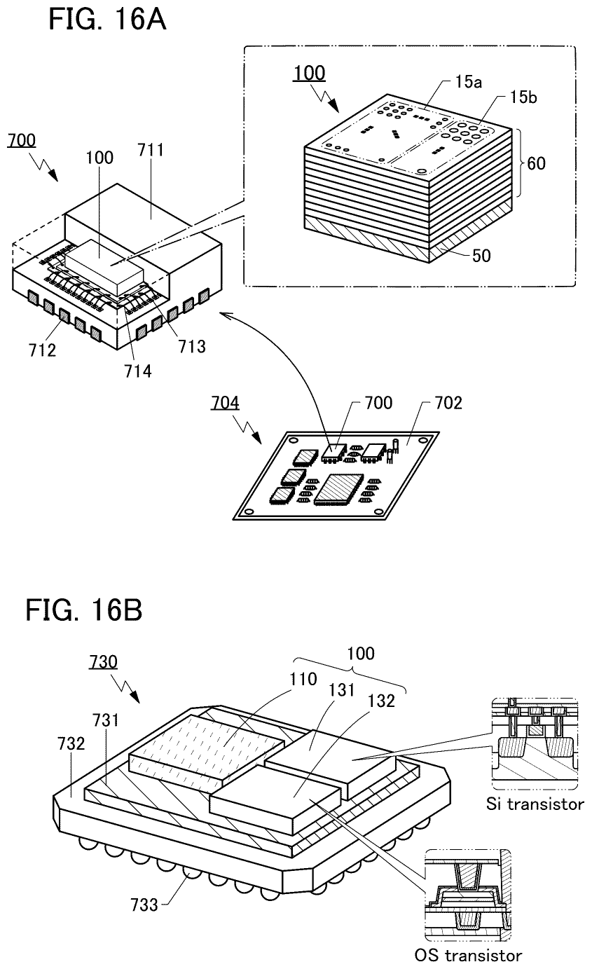

FIG. 16A is a perspective view of an electronic component 700 and a substrate (circuit board 704) on which the electronic component 700 is mounted. The electronic component 700 illustrated in FIG. 16A includes the memory device 100 that is a kind of a semiconductor device of one embodiment of the present invention in a mold 711. FIG. 16A omits illustrations of some parts to show the inside of the electronic component 700. The electronic component 700 includes a land 712 outside the mold 711. The land 712 is electrically connected to an electrode pad 713, and the electrode pad 713 is electrically connected to the memory device 100 via a wire 714. The electronic component 700 is mounted on a printed circuit board 702, for example. A plurality of such electronic components are combined and electrically connected to each other on the printed circuit board 702, whereby the mounting board 704 is completed.

FIG. 16B illustrates a perspective view of an electronic component 730. The electronic component 730 is an example of a SiP (System in package) or an MCM (Multi Chip Module). In the electronic component 730, an interposer 731 is provided over a package substrate 732 (printed circuit board), and the control means 110, the first memory portion 131, and the second memory portion 132 that form the memory device 100 are provided over the interposer 731. For example, the first memory portion 131 includes a memory element including a Si transistor, and the second memory portion 132 includes a memory element including an OS transistor.

As the package substrate 732, a ceramic substrate, a plastic substrate, a glass epoxy substrate, or the like can be used. As the interposer 731, a silicon interposer, a resin interposer, or the like can be used.

The interposer 731 includes a plurality of wirings and has a function of electrically connecting a plurality of integrated circuits with different terminal pitches. The plurality of wirings have a single-layer structure or a layered structure. The interposer 731 has a function of electrically connecting an integrated circuit provided on the interposer 731 to an electrode provided on the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. In the case of using a silicon interposer, a TSV (Through Silicon Via) can also be used as the through electrode.

A silicon interposer is preferably used as the interposer 731. The silicon interposer can be manufactured at lower cost than an integrated circuit because it is not necessary to provide an active element. Moreover, since wirings of the silicon interposer can be formed through a semiconductor process, the formation of minute wirings, which is difficult for a resin interposer, is easily achieved.

In a SiP, an MCM, or the like using a silicon interposer, a decrease in reliability due to a difference in expansion coefficient between an integrated circuit and the interposer is less likely to occur. Furthermore, a surface of a silicon interposer has high planarity, and a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

A heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the control means 110, the first memory portion 131, and the second memory portion 132 are preferably level with each other.

An electrode 733 may be provided on the bottom portion of the package substrate 732 to mount the electronic component 730 on another substrate. FIG. 16B illustrates an example in which the electrode 733 is formed of a solder ball. Solder balls are provided in a matrix on the bottom portion of the package substrate 732, whereby BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by various mounting methods not limited to BGA and PGA. For example, a mounting method such as SPGA (Staggered Pin Grid Array), LGA (Land Grid Array), QFP (Quad Flat Package), QFJ (Quad Flat J-leaded package), or QFN (Quad Flat Non-leaded package) can be employed.

This embodiment can be implemented in combination with the other embodiments described in this specification as appropriate.

### Embodiment 8

In this embodiment, application examples of the memory device of one embodiment of the present invention are described.

The memory device of one embodiment of the present invention can be applied to, for example, memory devices of a variety of electronic devices (e.g., information terminals, computers, smartphones, e-book readers, digital still cameras, video cameras, video recording/reproducing devices, navigation systems, game machines, and the like). In addition, the memory device can also be used for image sensors, IoT (Internet of Things), healthcare-related devices, and the like. Here, the computers refer not only to tablet computers, notebook computers, and desktop computers, but also to large computers such as server systems.

The memory device of one embodiment of the present invention is a memory device in which MBU hardly occurs and soft-error tolerance is high. The memory device of one embodiment of the present invention can retain written data accurately for a long period. Thus, the reliability of an electronic device including the memory device of one embodiment of the present invention can be increased.

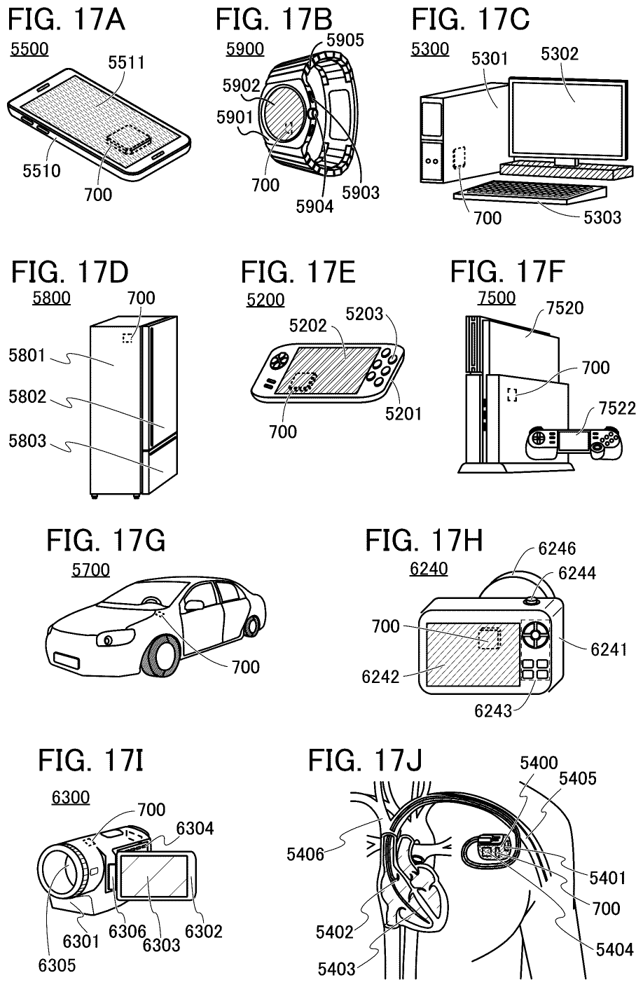

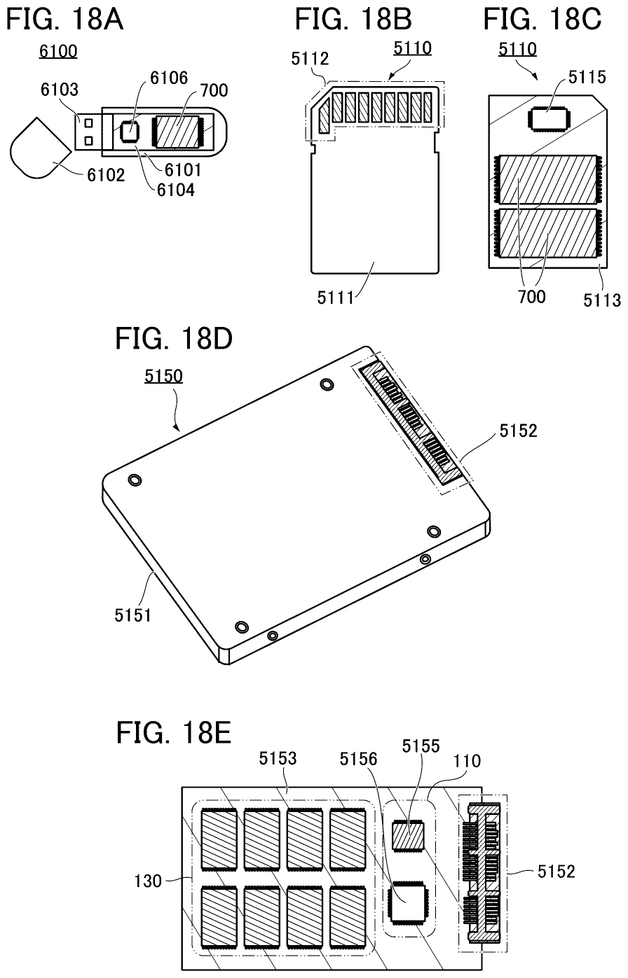

An example of an electronic device including a memory device according to one embodiment of the present invention is described. Note that FIG. 17A to FIG. 17J and FIG. 18A to FIG. 18E each illustrate a state where the electronic component 700 or the electronic component 730, each of which includes the memory device, is included in an electronic device.

### [Cellular Phone]

An information terminal 5500 illustrated in FIG. 17A is a cellular phone (smartphone), which is a type of information terminal. The information terminal 5500 includes a housing 5510 and a display portion 5511, and as input interfaces, a touch panel is provided in the display portion 5511 and a button is provided in the housing 5510.

By using the memory device according to one embodiment of the present invention, the information terminal 5500 can retain a temporary file generated at the time of executing an application (e.g., a web browser's cache or the like).

### [Wearable Terminal]

In addition, FIG. 17B illustrates an information terminal 5900 that is an example of a wearable terminal. The information terminal 5900 includes a housing 5901, a display portion 5902, an operation switch 5903, an operation switch 5904, a band 5905, and the like.

Like the information terminal 5500 described above, the wearable terminal can retain a temporary file generated at the time of executing an application by using the memory device according to one embodiment of the present invention.

### [Information Terminal]

In addition, FIG. 17C illustrates a desktop information terminal 5300. The desktop information terminal 5300 includes a main body 5301 of the information terminal, a display portion 5302, and a keyboard 5303.

Like the information terminal 5500 described above, the desktop information terminal 5300 can retain a temporary file generated at the time of executing an application by using the memory device according to one embodiment of the present invention.

Although the smartphone, the wearable terminal, and the desktop information terminal are respectively illustrated in FIG. 17A to FIG. 17C as examples of the electronic device, the memory device of one embodiment of the present invention can also be applied to an information terminal other than a smartphone, a wearable terminal, and a desktop information terminal. Examples of information terminals other than a smartphone, a wearable terminal, and a desktop information terminal include a PDA (Personal Digital Assistant), a laptop information terminal, and a workstation.

### [Household Appliance]

FIG. 17D illustrates an electric refrigerator-freezer 5800 as an example of a household appliance. The electric refrigerator-freezer 5800 includes a housing 5801, a refrigerator door 5802, a freezer door 5803, and the like. For example, the electric refrigerator-freezer 5800 is an electric refrigerator-freezer that is compatible with IoT (Internet of Things).

The memory device according to one embodiment of the present invention can be applied to the electric refrigerator-freezer 5800. The electric refrigerator-freezer 5800 can transmit and receive information on food stored in the electric refrigerator-freezer 5800 and food expiration dates, for example, to and from an information terminal and the like via the Internet. In the electric refrigerator-freezer 5800, the semiconductor device can retain a temporary file generated at the time of transmitting the information.

Although the electric refrigerator-freezer is described in this example as a household appliance, examples of other household appliances include a vacuum cleaner, a microwave oven, an electric oven, a rice cooker, a water heater, an IH cooker, a water server, a heating-cooling combination appliance such as an air conditioner, a washing machine, a drying machine, and an audiovisual appliance.

### [Game Machine]

In addition, FIG. 17E illustrates a portable game machine 5200 as an example of a game machine. The portable game machine 5200 includes a housing 5201, a display portion 5202, a button 5203, and the like.

In addition, FIG. 17F illustrates a stationary game machine 7500 as another example of a game machine. The stationary game machine 7500 includes a main body 7520 and a controller 7522. Note that the controller 7522 can be connected to the main body 7520 with or without a wire. Although not illustrated in FIG. 17F, the controller 7522 can include a display portion that displays a game image, and an input interface besides a button, such as a touch panel, a stick, a rotating knob, or a sliding knob, for example. The shape of the controller 7522 is not limited to that illustrated in FIG. 17F, and the shape of the controller 7522 may be changed in various ways in accordance with the genres of games. For example, for a shooting game such as an FPS (First Person Shooter) game, a gun-shaped controller having a trigger button can be used. As another example, for a music game or the like, a controller having a shape of a musical instrument, audio equipment, or the like can be used. Furthermore, the stationary game machine may include a camera, a depth sensor, a microphone, and the like so that the game player can play a game using a gesture or a voice instead of a controller.

Videos displayed on the game machine can be output with a display device such as a television device, a personal computer display, a game display, or a head-mounted display.

By using the memory device described in the above embodiment, the portable game machine 5200 or the stationary game machine 7500 can achieve low power consumption. Moreover, heat generation from a circuit can be reduced owing to low power consumption; thus, the influence of heat generation on the circuit itself, a peripheral circuit, and a module can be reduced.

Moreover, by using the memory device described in the above embodiment, the portable game machine 5200 or the stationary game machine 7500 can retain a temporary file necessary for arithmetic operation that occurs during game play.

As an example of a game machine, FIG. 17E illustrates a portable game machine. In addition, FIG. 17F illustrates a home-use stationary game machine. Note that an electronic device according to one embodiment of the present invention is not limited thereto. Examples of the electronic device according to one embodiment of the present invention include an arcade game machine installed in entertainment facilities (a game center, an amusement park, and the like), a throwing machine for batting practice installed in sports facilities, and the like.

### [Moving Vehicle]

The memory device described in the above embodiment can be used for a motor vehicle, which is a moving vehicle, and around the driver's seat in a motor vehicle.

FIG. 17G illustrates a motor vehicle 5700 as an example of a moving vehicle.

An instrument panel that provides various kinds of information by displaying a speedometer, a tachometer, a mileage, a fuel meter, a gearshift state, air-conditioning settings, and the like is provided around the driver's seat in the motor vehicle 5700. In addition, a memory device showing the above information may be provided around the driver's seat.

In particular, the display device can compensate for the view obstructed by a pillar or the like, blind areas for the driver's seat, and the like by displaying a video from an imaging device (not illustrated) provided for the motor vehicle 5700, which can increase safety. That is, display of an image from an imaging device provided on the outside of the motor vehicle 5700 can fill in blind areas and increase safety.

The semiconductor device described in the above embodiments can temporarily retain data; thus, the memory device can be used to retain temporary data necessary in a system conducting automatic driving, navigation, and risk prediction for the motor vehicle 5700, for example. The display device may be configured to display temporary information regarding navigation, risk prediction, or the like. Moreover, the memory device may be configured to retain a video of a driving recorder provided in the motor vehicle 5700.

Although a motor vehicle is described above as an example of a moving vehicle, the moving vehicle is not limited to a motor vehicle. Examples of moving vehicles include a train, a monorail train, a ship, and a flying object (a helicopter, an unmanned aircraft (a drone), an airplane, and a rocket).

### [Camera]

The memory device described in the above embodiment can be used in a camera.

FIG. 17H illustrates a digital camera 6240 as an example of an imaging device. The digital camera 6240 includes a housing 6241, a display portion 6242, operation switches 6243, a shutter button 6244, and the like, and a detachable lens 6246 is attached to the digital camera 6240. Although the digital camera 6240 is configured here such that the lens 6246 is detachable from the housing 6241 for replacement, the lens 6246 may be integrated with the housing 6241. In addition, the digital camera 6240 can be additionally equipped with a stroboscope, a viewfinder, or the like.

When the memory device described in the above embodiment is used in the digital camera 6240, imaging data can be accurately stored. According to one embodiment of the present invention, a memory device with low power consumption can be achieved. Thus, the digital camera 6240 with low power consumption can be achieved. Moreover, when power consumption is reduced, heat generation from a circuit can be reduced; thus, reduction in the reliability of the circuit itself, a peripheral circuit, and a module due to heat generation can be inhibited.

### [Video Camera]

The memory device described in the above embodiment can be used in a video camera.

FIG. 17I illustrates a video camera 6300 as an example of an imaging device. The video camera 6300 includes a first housing 6301, a second housing 6302, a display portion 6303, operation switches 6304, a lens 6305, a joint 6306, and the like. The operation switches 6304 and the lens 6305 are provided in the first housing 6301, and the display portion 6303 is provided in the second housing 6302. The first housing 6301 and the second housing 6302 are connected to each other with the joint 6306, and an angle between the first housing 6301 and the second housing 6302 can be changed with the joint 6306. Images displayed on the display portion 6303 may be changed in accordance with the angle at the joint 6306 between the first housing 6301 and the second housing 6302.

When images taken by the video camera 6300 are recorded, the images need to be encoded in accordance with a data recording format. By using the above semiconductor device, the video camera 6300 can retain a temporary file generated in encoding.

### [ICD]

The memory device described in the above embodiment can be used in an implantable cardioverter-defibrillator (ICD).

FIG. 17J is a schematic cross-sectional view showing an example of an ICD. An ICD main unit 5400 includes at least a battery 5401, the electronic component 700, a regulator, a control circuit, an antenna 5404, a wire 5402 reaching a right atrium, and a wire 5403 reaching a right ventricle.

The ICD main unit 5400 is implanted in the body by surgery, and the two wires pass through a subclavian vein 5405 and a superior vena cava 5406 of the human body, with an end of one of the wires placed in the right ventricle and an end of the other wire placed in the right atrium.

The ICD main unit 5400 functions as a pacemaker and paces the heart when the heart rate is not within a predetermined range. In addition, when the heart rate is not recovered by pacing (e.g., when ventricular tachycardia or ventricular fibrillation occurs), treatment with an electrical shock is performed.

The ICD main unit 5400 needs to monitor the heart rate all the time in order to perform pacing and deliver electrical shocks as appropriate. For that reason, the ICD main unit 5400 includes a sensor for measuring the heart rate. In the ICD main unit 5400, data on the heart rate obtained by the sensor or the like, the number of times the treatment with pacing is performed, and the time taken for the treatment, for example, can be stored in the electronic component 700.

The antenna 5404 can receive power, and the battery 5401 is charged with the power. Furthermore, when the ICD main unit 5400 includes a plurality of batteries, safety can be increased. Specifically, even when some of the batteries in the ICD main unit 5400 are dead, the other batteries can function properly; thus, the batteries also function as an auxiliary power source.

In addition to the antenna 5404 capable of receiving power, an antenna that can transmit physiological signals may be included to construct, for example, a system that monitors cardiac activity by checking physiological signals such as a pulse, a respiratory rate, a heart rate, and body temperature with an external monitoring device.

### [Expansion Device for PC]

The memory device described in the above embodiment can be used in a calculator such as a PC (Personal Computer) and an expansion device for an information terminal.

FIG. 18A illustrates, as an example of the expansion device, a portable expansion device 6100 that includes a chip capable of storing information and is externally provided on a PC. The expansion device 6100 can store information using the chip when connected to a PC with a USB (Universal Serial Bus) or the like, for example. Note that FIG. 18A illustrates the portable expansion device 6100; however, the expansion device according to one embodiment of the present invention is not limited thereto and may be a comparatively large expansion device including a cooling fan or the like, for example.

The expansion device 6100 includes a housing 6101, a cap 6102, a USB connector 6103, and a substrate 6104. The substrate 6104 is held in the housing 6101. The substrate 6104 is provided with a circuit for driving the semiconductor device or the like described in the above embodiment. For example, the substrate 6104 is provided with the electronic component 700 and a controller chip 6106. The USB connector 6103 functions as an interface for connection to an external device.

### [Sd Card]

The memory device described in the above embodiment can be used in an SD card that can be attached to an electronic device such as an information terminal or a digital camera.

FIG. 18B is a schematic external view of an SD card, and FIG. 18C is a schematic view of the internal structure of the SD card. An SD card 5110 includes a housing 5111, a connector 5112, and a substrate 5113. The connector 5112 functions as an interface for connection to an external device. The substrate 5113 is held in the housing 5111. The substrate 5113 is provided with a memory device and a circuit for driving the memory device. For example, electronic components 700 and a controller chip 5115 are attached to the substrate 5113. Note that the circuit structures of the electronic components 700 and the controller chip 5115 are not limited to those described above, and can be changed as appropriate according to circumstances. For example, a write circuit, a row driver, a read circuit, and the like that are provided in an electronic component may be incorporated into the controller chip 5115 instead of the electronic component 700.

When the electronic components 700 are provided also on a rear surface side of the substrate 5113, the capacitance of the SD card 5110 can be increased. In addition, a wireless chip with a wireless communication function may be provided on the substrate 5113. This allows wireless communication between an external device and the SD card 5110 and enables data reading and writing from and to the electronic components 700.

### [SSD]

The memory device described in the above embodiment can be used in an SSD (Solid State Drive) that can be attached to an electronic device such as an information terminal.

FIG. 18D is a schematic external view of an SSD, and FIG. 18E is a schematic view of the internal structure of the SSD. An SSD 5150 includes a housing 5151, a connector 5152, and a substrate 5153. The connector 5152 functions as an interface for connection to an external device. The substrate 5153 is held in the housing 5151. The substrate 5153 is provided with a memory device and a circuit for driving the memory device.

For example, the memory means 130, a memory chip 5155, and a controller chip 5156 are attached to the substrate 5153. When the memory means 130 is also provided on a rear surface side of the substrate 5153, the memory capacity of the SSD 5150 can be increased. A work memory is incorporated in the memory chip 5155. For example, a DRAM chip is used as the memory chip 5155. A processor, an ECC circuit, and the like are incorporated in the controller chip 5156. The memory chip 5155 and the controller chip 5156 correspond to the control means 110.

Note that the circuit structures of the memory means 130, the memory chip 5155, and the controller chip 5156 are not limited to those described above, and the circuit structures can be changed as appropriate according to circumstances. For example, a memory functioning as a work memory may also be provided in the controller chip 5156.

### [Computer]

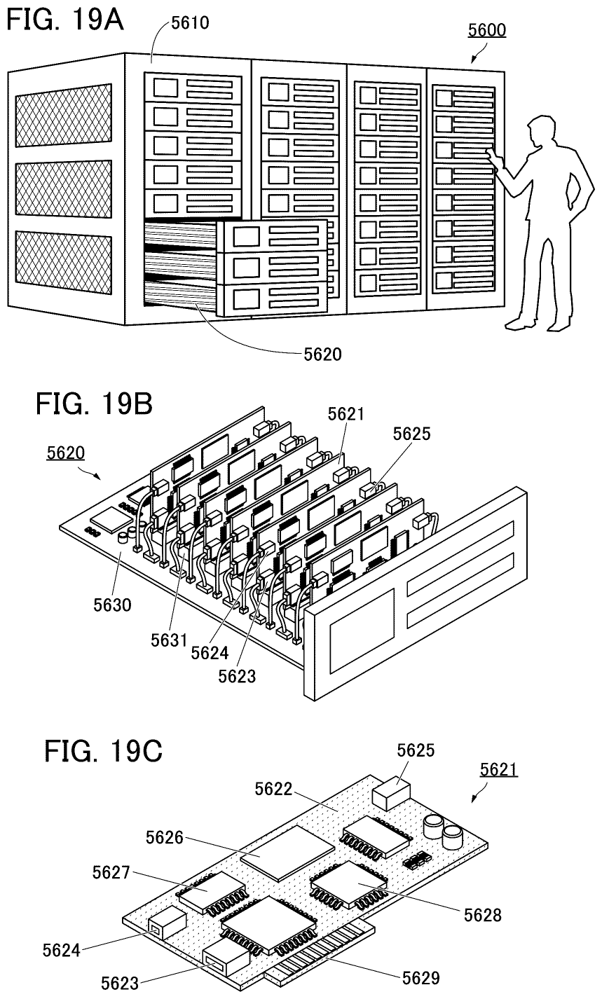

A computer 5600 illustrated in FIG. 19A is an example of a large computer. In the computer 5600, a plurality of rack mount computers 5620 are stored in a rack 5610.

The computer 5620 can have a structure in a perspective view illustrated in FIG. 19B, for example. In FIG. 19B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 19C is an example of a processing board provided with a CPU, a GPU, a memory device, and the like. The PC card 5621 includes a board 5622. The board 5622 includes a connection terminal 5623, a connection terminal 5624, a connection terminal 5625, a semiconductor device 5626, a semiconductor device 5627, a semiconductor device 5628, and a connection terminal 5629. Note that FIG. 19C also illustrates semiconductor devices other than the semiconductor device 5626, the semiconductor device 5627, and the semiconductor device 5628, the following description of the semiconductor device 5626, the semiconductor device 5627, and the semiconductor device 5628 is referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. As another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA (Field Programmable Gate Array), a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device or the like. As the semiconductor device 5628, the electronic component 700 according to one embodiment of the present invention can be used, for example.

The computer 5600 can also function as a parallel computer. When the computer 5600 is used as a parallel computer, large-scale computation necessary for artificial intelligence learning and inference can be performed, for example.

The memory device of one embodiment of the present invention has high soft-error tolerance, and written data can be retained accurately for a long period. Accordingly, with the use of the memory device of one embodiment of the present invention in a variety of electronic devices or the like described above, accurate arithmetic processing can be performed.

The memory device of one embodiment of the present invention is used in a variety of electronic devices or the like described above, so that a reduction in size and a reduction in power consumption of the electronic device can be achieved. In addition, since the memory device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the memory device of one embodiment of the present invention can achieve an electronic device that operates stably even in a high temperature environment. Thus, the reliability of the electronic device can be increased.

This embodiment can be implemented in combination with the other embodiments described in this specification as appropriate.

### Embodiment 9

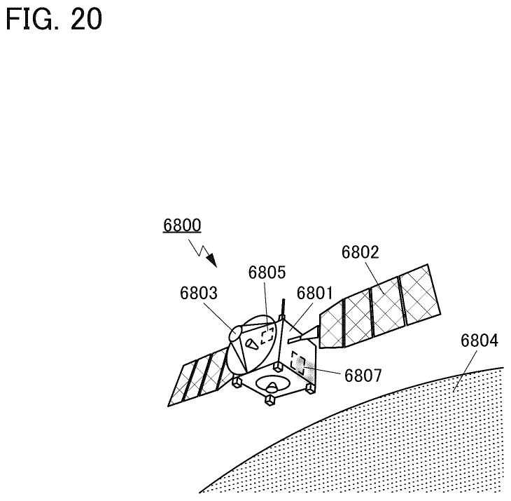

In this embodiment, a specific example of a case where the memory device of one embodiment of the present invention is applied to a device for space is described with reference to FIG. 20.

The memory device of one embodiment of the present invention includes an OS transistor. A change in electrical characteristics of the OS transistor due to exposure to radiation is small. That is, the OS transistor is highly resistant to radiation, and thus can be suitably used even in an environment where radiation can enter. For example, the OS transistor can be suitably used in outer space.

FIG. 20 illustrates an artificial satellite 6800 as an example of a device for space. The artificial satellite 6800 includes a body 6801, a solar panel 6802, an antenna 6803, a secondary battery 6805, and a control device 6807. Note that FIG. 20 illustrates a planet 6804 in outer space, for example. Note that outer space refers to, for example, space at an altitude greater than or equal to 100 km, and outer space in this specification may also include one or more of thermosphere, mesosphere, and stratosphere.

The amount of radiation in outer space is 100 or more times that on the ground. Note that examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for the operation of the artificial satellite 6800 is generated. However, for example, in the situation where the solar panel is not irradiated with sunlight or the amount of sunlight with which the solar panel is irradiated is small, the amount of generated electric power is small. Accordingly, a sufficient amount of electric power required for the operation of the artificial satellite 6800 might not be generated. In order to operate the artificial satellite 6800 even with a small amount of generated electric power, the artificial satellite 6800 is preferably provided with the secondary battery 6805. Note that the solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. The control device 6807 includes a memory device. Note that the semiconductor device including the OS transistor, such as the memory device of one embodiment of the present invention, is suitably used for the control device 6807. A change in electrical characteristics due to exposure to radiation is smaller in the OS transistor than in a Si transistor. Accordingly, the OS transistor has high reliability and thus can be suitably used even in an environment where radiation can enter.

Alternatively, the artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of a device for space in this embodiment, the present invention is not limited thereto. The semiconductor device of one embodiment of the present invention can be suitably used for a device for space such as a spacecraft, a space capsule, or a space probe, for example.

### REFERENCE NUMERALS

10: memory cell, 15: memory array, 100: memory device, 110: control means, 111: control portion, 112: external interface, 113: memory interface, 114: application memory, 115: working memory, 120: ECC portion, 121: check bit generation portion, 122: error detection portion, 123: error correction portion, 130: memory means, 131: first memory portion, 132: second memory portion, 133: memory portion

1. A memory device comprising:
a check bit generation portion generating a check bit from an information bit;
a first memory portion storing the information bit;
a second memory portion storing the check bit;
an error detection portion performing arithmetic processing using the information bit stored in the first memory portion and the check bit stored in the second memory portion; and
an error correction portion correcting the information bit or the check bit in accordance with a result of the arithmetic processing,
wherein the first memory portion comprises a first transistor,
wherein the second memory portion comprises a second transistor, and
wherein a semiconductor layer of the second transistor and a semiconductor layer of the first transistor have different compositions.

2. The memory device according to claim 1,
wherein the first transistor is a Si transistor, and
wherein the second transistor is an OS transistor.

3. An operation method of a memory device, the memory device comprising:
a check bit generation portion;
an error detection portion and an error correction portion;
a first memory portion comprising a first transistor; and
a second memory portion comprising a second transistor,
the operation method of the memory device, comprising the steps of:
generating a check bit in the check bit generation portion using an information bit;
writing the information bit to the first memory portion;
writing the check bit to the second memory portion;
performing arithmetic processing in the error detection portion using the information bit stored in the first memory portion and the check bit stored in the second memory portion;
correcting an error of the information bit or the check bit in accordance with a result of the arithmetic processing in the error correction portion;
storing the information bit subjected to the correction in the first memory portion; and
storing the check bit subjected to the correction in the second memory portion.

4. The operation method of the memory device according to claim 3,
wherein configuration bits of the information bit are not stored in successive physical addresses.

5. The operation method of the memory device according to claim 3,
wherein configuration bits of the check bit are not stored in successive physical addresses.

6. The operation method of the memory device according to claim 3,
wherein the first transistor is a Si transistor, and
wherein the second transistor is an OS transistor.

7. An operation method of a memory device comprising the steps of:
generating a check bit using an information bit;
storing the information bit in a first memory portion;
storing the check bit in a second memory portion;
performing arithmetic processing using the information bit stored in the first memory portion and the check bit stored in the second memory portion;
correcting the information bit or the check bit in accordance with a result of the arithmetic processing;
in a case where the information bit is corrected, storing the information bit subjected to the correction in the first memory portion; and
in a case where the check bit is corrected, storing the check bit subjected to the correction in the second memory portion.

8. The operation method of a memory device according to claim 7,
wherein configuration bits of the information bit are not stored in successive physical addresses.

9. The operation method of a memory device according to claim 7,
wherein configuration bits of the check bit are not stored in successive physical addresses.

10. The operation method of a memory device according to claim 7,
wherein the first memory portion comprises a Si transistor, and
wherein the second memory portion comprises an OS transistor.

11. A program to make a memory device execute the operation method according to claim 3.

12. A program to make a memory device execute the operation method according to claim 7.
